(19) United States
(12) Patent Application Publication
(10) Pub. No.: US 2006/0148124 A1
(43) Pub. Date: Jul. 6, 2006

(54) Nanoparticle conjugates and method of production thereof

(76) Inventor: Robert Wilson, Liverpool (GB)

Correspondence Address: BOYLE FREDRICKSON NEWHOLM STEIN & GRATZ, S.C., 250 E. WISCONSIN AVENUE, SUITE 1030, MILWAUKEE, WI, 53202, US

(21) Appl. No.: 10/537,164

(22) PCT Filed: Nov. 28, 2003
(86) PCT No.: PCT/GB03/05157

§ 371 Date: Oct. 31, 2005

(30) Foreign Application Priority Data
Nov. 28, 2002 (GB) 0227738.2

(51) Int. Cl. H01L 21/00

(52) U.S. Cl. 438/82; 257/E51.039; 977/734

(57) ABSTRACT

The present invention provides a method for the preparation of nanoparticle conjugates comprising: protocols for synthesizing intermediate product molecules by introducing known numbers of two or more substituents into a flexible hydrophilic polymer, where one substituent is capable, optionally after deprotection, of binding to a nanoparticle, and where the other substituents are capable of participating in analytical or other applications; protocols for contacting the intermediate product molecules with nanoparticles for a period of time and under conditions effective to allow the binding of a known number of the intermediate product molecules to each nanoparticle to provide the nanoparticle conjugate.

The present invention relates to nanoparticle conjugates, in particular those which are useful in biomolecular assays, and to methods for their production.

Recent developments in nano-technology have suggested that it may be possible to use nanoparticles in detection, diagnostics, sensing and other applications (Review Article: Angew. Chem. Int. Ed., 40 (2001) 4128-4158). In so doing, however, it is important to remember that the quality of the nanoparticle is only one of several factors that contribute to the sensitivity and reliability of these applications. The sensitivity depends on the minimum signal that can be distinguished from the background, and any factors that contribute to this will reduce the sensitivity. In biomolecular assays a major source of background is non-specific adsorption and any conjugation method should seek to minimize this. In free solution the reaction between two binding molecules such as an antibody and its corresponding antigen is extremely fast, and a further requirement of any conjugation method is that, as far as possible, it should not hinder this reaction. One of the most exciting opportunities to have emerged from the integration of nanotechnology and analytical chemistry, is the possibility of fine tuning the optical properties of nanoparticles so that more than one analyte can be determined in the same sample (J. Am. Chem. Soc., 123 (2001) 5164-5165), but if reliable results are to be obtained it is important to ensure that conjugated molecules are unable to exchange from one particle to another.

Nanoparticle conjugates that interact with biological systems have recently attracted widespread interest in biology and medicine. These conjugates are believed to have potential as novel intravascular probes for both sensing (e.g., imaging) and therapeutic purposes (e.g., drug delivery) (Proc. Natl. Acad. Sci. USA, 99 (2002) 12617-12621). The requirements of these conjugates are in many respects similar to those used in biomolecular assays, but a further requirement is that the conjugate should be biocompatible and, for in vivo applications, should be biodegradable or able to pass through the biological particulate filter known as the reticuloendothelial system.

Most proteins contain chemical groups (—NH₂, —SH₂, etc.) that bind strongly to certain types of nanoparticle, but if necessary the number of such groups can be increased with, for example, a thiolating reagent such as 2-iminothiolane, or by genetic engineering. Fine details of the process by which proteins become non-specifically bound to nanoparticles are not well understood, but it has been postulated that a series of electrostatic and chemical interactions accompanied by conformation changes is involved. The most widespread use of this method is for conjugating antibodies to gold nanoparticles (J. Histochem. Cytochem., 36 (1988) 401-407 and Biotechnic & Histochem., 75 (2002) 203-242). A small excess of antibodies are incubated with the nanoparticles for a short time under alkaline conditions. Then unbound protein is removed and the conjugate is stabilized with a blocking agent such as polyethylene glycol. The optimal amount of protein required for conjugation can be determined by means of a flocculation assay. When electrolytes are added to incompletely conjugated particles they flocculate. The flocculation of gold nanoparticles can be monitored by the decrease and/or red shift of the plasmon absorption band at about 520 nm. Non-specifically conjugated proteins stabilize the nanoparticles by mutual repulsion. The minimum amount of protein needed to prevent flocculation is determined by titration and often corresponds to a single monolayer bound to the surface of the nanoparticles. Other proteins have been conjugated by similar methods, and small molecules such as oligonucleotides and haptens can be conjugated after covalent attachment to a suitable carrier protein. The main problem with these conjugation methods is that bound proteins are known to desorb (Immuno-gold Labeling In Cell Biology [Verkleij and Leuniissen eds.] CRC Press, Boca Raton, Fla., (1989) pp 49-60; J. Histochem. Cytochem. 39 (1991) 37-39).

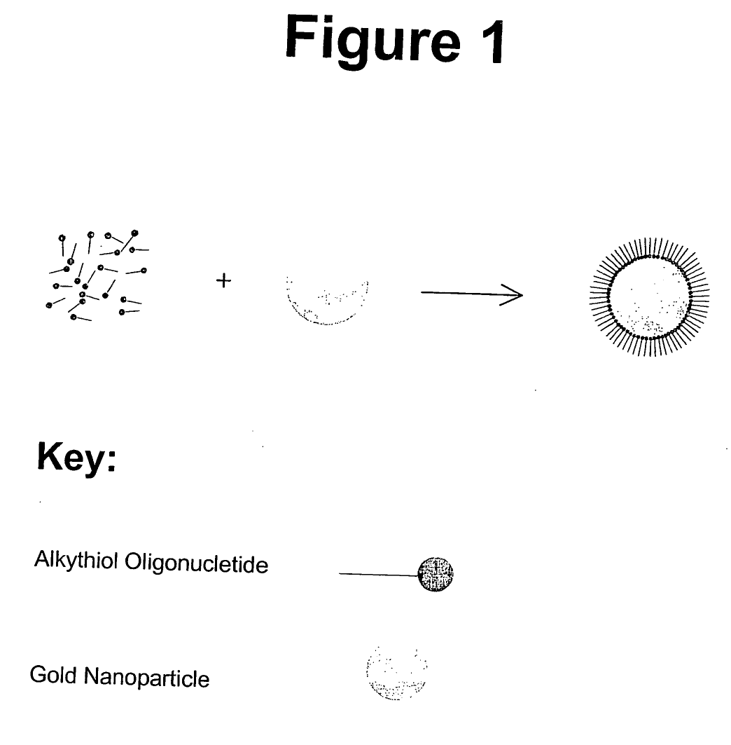

Monovalent methods of conjugation involve incubating the nanoparticles with an excess of molecules that comprise a chemical group that binds to the particles and a binding site that can participate in biomolecular or other applications (as shown in FIG. 1). Unbound molecules are removed in a subsequent purification step such as ultra-centrifugation or gel exclusion chromatography. Monovalent conjugation may also be the first step in a more complicated protocol. A recent conference report described the conjugation of long chain mercaptoalcohols to gold nanoparticles (Presented by V. H. Perez-Luna at the Nanotechnology in bioengineering: applications to detection, diagnostics and sensing conference 7 Nov., 2002, Indiana, USA). Subsequently the alcohol groups were activated with epichlorohydrin and conjugated to a layer of dextran. Carboxylic acid groups were introduced into the dextran with bromoacetic acid and then coupled to biotin. This is an adaptation of a protocol used to lay down immunosorbent surfaces on macroscopic gold substrates for surface plasmon resonance (SPR) assays (as detailed in WO-A-90/05303), but when it is used with nanoparticles the large number of chemical and purification steps results in low yields.

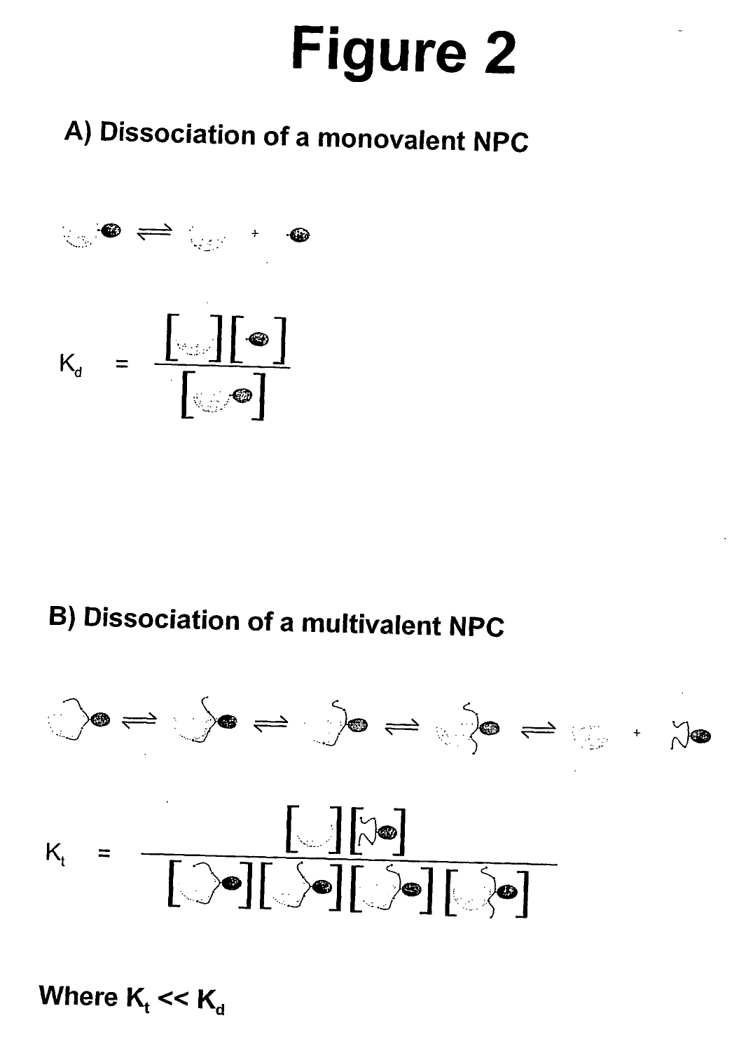

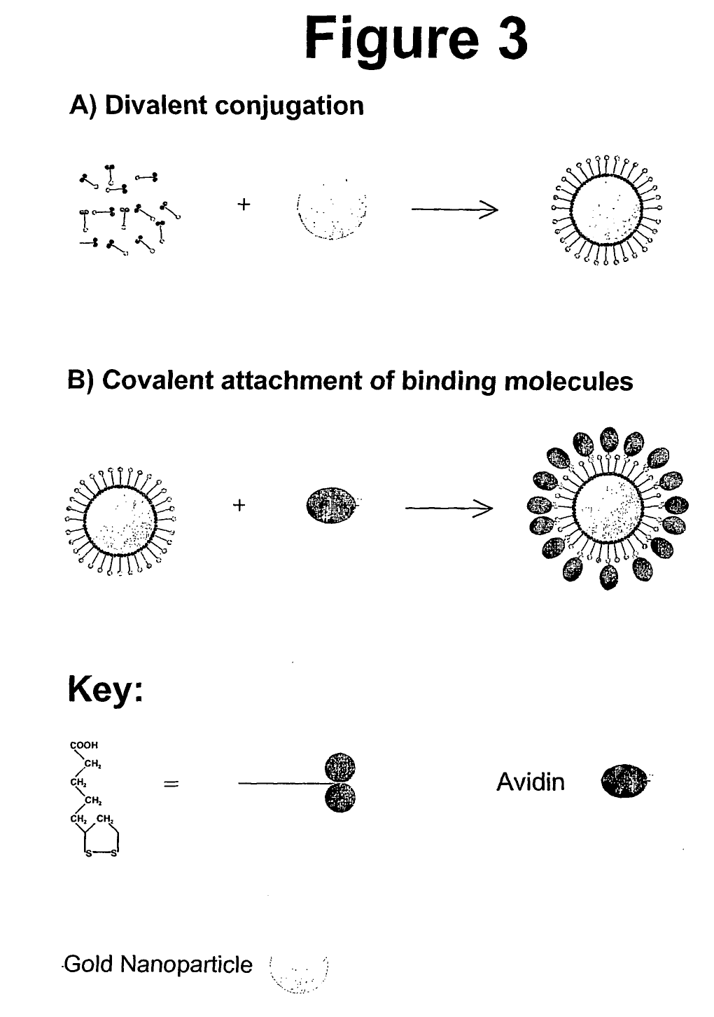

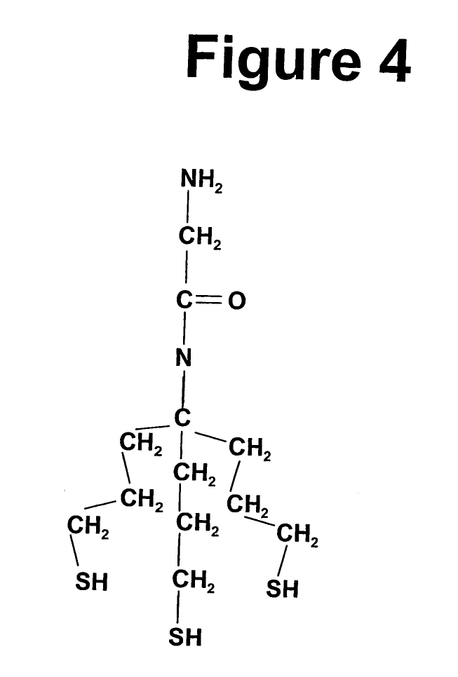

Molecules conjugated to nanoparticles by conjugation substituents such as —SH and —NH₂ are in equilibrium with unbound molecules in solution. They must be tightly bound to ensure that they remain conjugated, but even mercapto compounds bound to gold can dissociate (Langmuir, 17 (2001) 4836-4843). One solution to this problem is to conjugate molecules to the particles multivalently by more than one conjugation substituent. The equilibria that exist between bound molecules and their corresponding dissociation products are shown in FIG. 2. Monovalent conjugates are characterized by a single dissociation constant K_{d} which depends on the affinity of individual conjugation substituents for the nanoparticle, but multivalent conjugates are characterized by a series of dissociation constants (combined in Kₜ). There are several reports of conjugates based on divalent molecules such as dihydrolipoic acid (FIG. 3) and one describing the use of trivalent aminotrithiolate (FIG. 4) for conjugating antibodies to metallic nanoparticles (as detailed in U.S. Pat. No. 5,945,293). The latter compound was originally synthesized for multivalent attachment of peptides to macroscopic gold substrates (Science, 261 (1993) 73-76). It remained bound to these substrates even when it was heated to 180° C. for 7 days.

The extent to which a conjugation substituent bound to a nanoparticle enhances the binding of a second conjugation substituent to the same nanoparticle depends on the distance by which the conjugation substituents are separated, and the amount of steric hindrance exerted by the chemical structure that links them together. Dextrans are flexible polymers of glucose that are known to resist non-specific adsorption and allow fast kinetics in biomolecular assays (Sensor Actuat. B-Chem., 5 (1991) 78-84; Biomaterials, 21 (2000) 957-966). The same flexibility that favours fast kinetics also reduces the amount of steric hindrance between conjugation substituents in the same multivalent molecule. When primary amines are substituted into dextrans the aminodextran (amdex) products can form multivalent conjugates with metal and semiconductor nanoparticles (see U.S. Pat. Nos. 5,248,772; 5,552,086 and 5,945,293 and Langmuir, 16 (2000) 3107-3118). Aminodextrans have been used to conjugate biochemically active molecules such as ouabain to gold nanoparticles (Eur. J. Cell Biol. 45 (1987) 200-208; Invest. Opthalmol. & Vis. Sci., 26 (1985) 1002-1013; J. Cell Biol., 105 (1987) 2589-2601; J. Bacteriol., 169 (1987) 3531-3538).

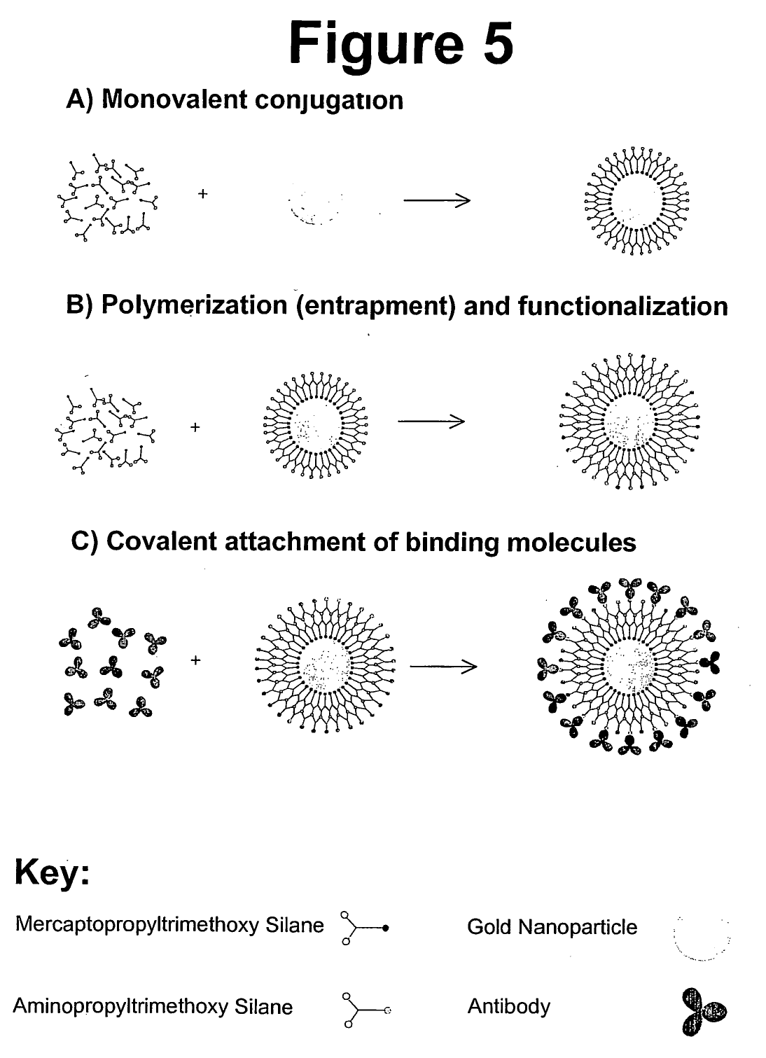

The problem of nanoparticle conjugate dissociation can also be avoided by entrapping the particles in a shell from which they are unable to escape (FIG. 5). Metallic and semiconductor nanoparticles can be entrapped in a shell formed by polymerization of mercaptopropyltrimethoxy silane (Langmuir, 13 (1997) 3921-3926; Chem. Mater. 14 (2002) 2113-2119). The shell confers stability on the nanoparticles and further reaction with other silanes introduces functional groups that can be covalently attached to binding molecules such as biotin (Chem. Mater. 14 (2002) 2113-2119). Nanoparticles can also be entrapped by cross-linking dextran with epichlorohydrin (Bioconjugate. Chem. 10 (1999) 186-191; Bioconjugate Chem. 11 (2000) 941-946). Primary amines can be introduced into the dextran by reductive amination and covalently attached to proteins. Nanoparticle conjugates prepared in this way have been used for non-invasive magnetic resonance imaging and cancer therapy. When nanoparticles are exposed to a succession of polyelectrolyte solutions of alternating charge they become entrapped in a polymer shell that is robust enough to remain intact when core particle is dissolved. Gold nanoparticles coated with an anionic layer of monovalent mercapto compounds have subsequently been entrapped in alternate layers of sodium poly(styrenesulfonate) and poly(diallyldimethylammonium) chloride (J. Phys. Chem. B, 103 (2001) 6846-6852). Although this layer-by-layer (LbL) approach has not yet been used to prepare nanoparticle conjugates, it has been used to conjugate antibodies to polystyrene microbeads (J. Colloid Interface Sci., 234 (2001) 356-362).

Biomolecular binding assays can be divided into two categories depending on whether the concentration of the labeled reagent is 1) higher than the concentration of the analyte or 2) about the same as or less than the concentration of the analyte. The former (1) are known as regent excess assays and the latter (2) are known as reagent limited assays. A sandwich immunoassay is an example of a regent excess assay and a competitive immunoassay is an example of a reagent limited assay. The importance of this distinction between reagent excess and reagent limited assays has been recognized for many years. It is known to determine what factors will ultimately limit the sensitivity of an assay (Principles and Practice of Immunoassay, 2nd ed. (1997) Macmillan, pp 173-207 and Chem. Ed. 76 (1999) 769-780). The sensitivity of reagent excess immunoassays, for example, are limited by non-specific binding, but the sensitivity of reagent limited immunoassays are limited by the affinity (Kₐ value) of the probe for the analyte. At equilibrium the reaction of a biomolecular binding molecule with the analyte is described by the equation:

$$\begin{matrix}{K}_{a} = \frac{[ PA ]}{[ P ] [ A ]} & I \\ {K}_{a} = {k}_{a} / {k}_{d} Where [ P ] + [ A ] {{⇌}^{ {k}_{a }}}_{{k}_{d}} [ PA ] & II\end{matrix}$$

Where Kₐ is known as the intrinsic affinity of the probe molecule, [PA] is the concentration of the probe molecule bound to the analyte, [P] is the free probe molecule concentration and [A] is the free analyte concentration. Kₐ is equal to the ratio of the association and dissociation rate constants: Any factor that increases the association rate constant (kₐ) or decreases the dissociation rate constant (k_{d}) will increase the intrinsic affinity (Kₐ) of the probe molecule for the analyte. One reason why nanoparticle labels are interesting is because they provide a way to increase kₐ and decrease k_{d}. Before discussing how this can be done it is necessary to define another value known as the functional affinity. Equations I and II describe the equilibrium between a monovalent probe molecule and the analyte, but many probe molecules have more than one binding site. The antibodies most often used in immunoassays, for example, are bivalent, which means that in some cases one antibody may be bound to the same analyte molecule by two binding sites. When this happens the reaction at equilibrium is described by the equation:

$${K}_{f} = \frac{[ {PA}_{2} ] [ {P2A}_{1} ] [ {PA}_{1} ]}{[ P ] [ A ]} \qquad III$$

where K_{f} is known as the functional affinity of the probe molecule, and the numerical subscripts indicate the number of bonds between the probe molecule and the analyte. The value of K_{f} may be orders of magnitude greater than the value of Kₐ indicating that the probe molecule is more tightly bound to the analyte. The increase in K_{f} is due to a decrease in the value of k_{d}.

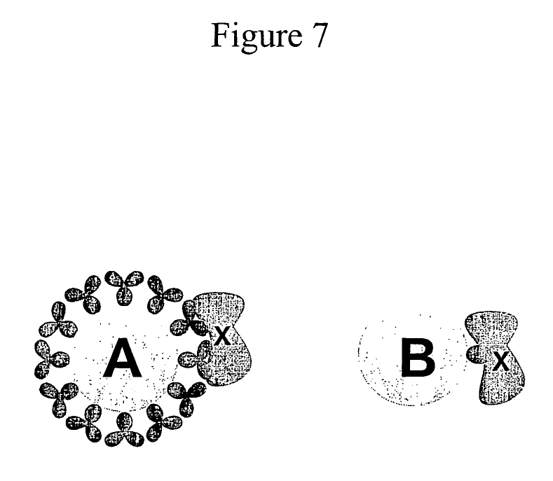

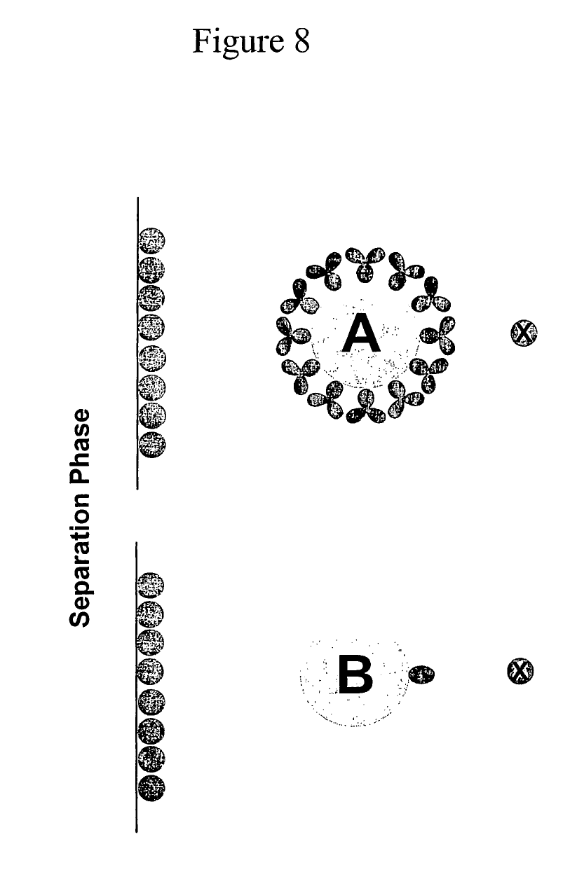

FIG. 7 shows two nanoparticle conjugates (NPCs) in solution with a molecule of the corresponding analyte. Conjugate A has many identical probe molecules conjugated to the same nanoparticle and conjugate B has only one probe molecule of the same type conjugated to a nanoparticle. Conjugate A has a much higher probability of binding to the analyte X because most of the surface of conjugate B does not have any binding sites. The value of kₐ for conjugate A is higher than for conjugate B and therefore the value of K_{f} is also higher. FIG. 8 shows the same nanoparticle conjugates A and B bound to the corresponding analyte. In this example, however, one molecule of the analyte X can accommodate more than one binding site and therefore conjugate A, but not conjugate B, can participate in polyvalent binding. Polyvalent binding decreases the value of k_{d}, as explained above, and therefore once again conjugate A has a higher value of K_{f} than conjugate B. These observations suggest that the K_{f} values of NPCs can be altered by modulating the numbers of probe molecules conjugated to each particle.

Several groups have studied the effect of modulating the number of probe molecules conjugated to a nanoparticle on the sensitivity of biomolecular (Anal. Chem. 73 (2001) 2254-2260; Anal. Biochem. 202 (1992) 120-125; Anal. Biochem. 253 (1997) 112-122; and Anal. Biochem. 272 (1999) 165-170). Soukka et al. found that the sensitivity of reagent excess immunoassays increased linearly as the number of antibodies increased (Anal. Chem. 73 (2001) 2254-2260). They could not detect an upper limit at which the numbers of antibodies conjugated to each nanoparticle no longer resulted in an increase in sensitivity. By contrast, other studies have found that the sensitivity of reagent excess assays increased to a maximum, and then decreased, as the number of probe molecules conjugated to each nanoparticle was increased. Although more work is required, the inference from these reports is that maximum sensitivity in reagent excess assays corresponds to high, or at least moderately high, numbers of probe molecules per nanoparticle.

The situation in reagent limited assays is more complicated because the sensitivity may be influenced by the density of binding sites on the separation phase as well as the number of probe molecules conjugated to each nanoparticle. When carrying out reagent limited immunoassays for TNT Wilson et al. found that the sensitivity could be increased by using monovalent Fab fragments instead of bivalent whole antibodies (Anal. Chem. 75 (2003) 4244-4249). The sensitivity increased because the Fab fragments had a similar functional affinity for the separation phase as the analyte. Bivalent whole antibodies had a higher functional affinity for the separation phase (a high affinity haptenylated dextran surface) than the analyte, and therefore high concentrations of analyte were required to produce a measurable change in the number of bivalent antibodies bound to the separation phase. When nanoparticles conjugated to a plurality of probe molecules are used, the potential for polyvalent binding to the separation phase, accompanied by a decrease in sensitivity, is even greater than when bivalent antibodies are used.

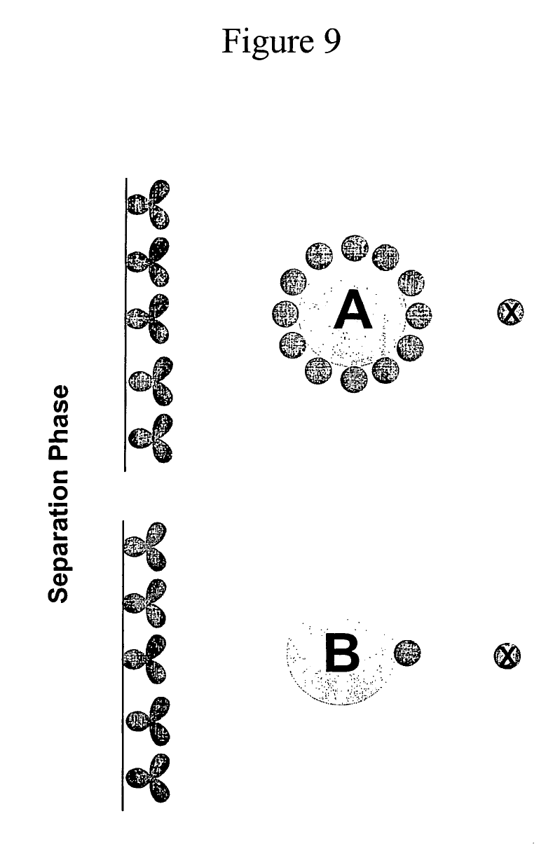

A further complication when considering reagent limited assays is that there are two possible formats based on 1) probe molecules conjugated to nanoparticles and 2) analyte analogues conjugated to nanoparticles. An example of the former 1) would be where the nanoparticles are conjugated to antibodies and an example of the latter 2) would be where haptens are conjugated to nanoparticles. FIGS. 9A and B shows the situation when nanoparticles are conjugated to A) high and B) low numbers of probe molecules. The value of kₐ for the binding of the conjugate to the analyte and the separation phase both increase as the numbers of probe molecules increase. This increase is accompanied by an increase in sensitivity provided polyvalent binding to the separation phase does not occur. When polyvalent binding to the separation phase does occur, high concentrations of analyte are required to produce a measurable change in the amount of conjugate bound to the separation phase, and sensitivity is low. This is what Goldman et al. found when they carried out reagent limited immunoassays for TNT with semiconductor nanoparticles conjugated to a mean ˜3 antibodies (Anal. Chem. 74 (2002) 841-847). It follows from these observations that sensitivity is a function of the relationship between the number of probe molecules conjugated to the nanoparticles and the density of binding molecules on the separation phase. Maximum sensitivity is attained when the maximum number of probe molecules that do not permit polyvalent binding are conjugated to the particles. FIG. 9B shows the situation where nanopartilces are conjugated to A) high and B) low numbers of analyte analogues. The value of kₐ is unaffected by an increase in the number of analyte analogues conjugated to each particle and therefore there is no increase in sensitivity. Nanoparticles conjugated to high numbers of analyte molecules, however, can participate in polyvalent binding to the separation phase. Maximum sensitivity in this type of reagent limited immunoassay is attained when low numbers of analyte analogues are conjugated to each nanoparticles.

It can therefore be clearly seen that an ability to modulate the numbers of probe molecules conjugated to a nanoparticles has important implications for the sensitivity of biomolecular assays. In previous work where the number of probe molecules has been modulated the numbers have been determined at the level of the final conjugate. This work involves complicated methodology and sensitive measurements that are prone to error. A particular advantage of the band-in-glove method described here is that it allows the number of probe molecules to be determined prior to conjugation. The probe molecules are linked to a high molecular weight dextran, which is then conjugated to the particles by a process of self-assembly. The number of probe molecules conjugated to each particle is determined by the relationship between the size of the dextran and the diameter of the nanoparticles.

The similarity in size between nanoparticles and biological molecules also makes them suitable for in vivo applications. The requirements of these nanoparticle conjugates are in many respects similar to those used in biomolecular assays, except that the analytical probe molecules are replaced with other functional molecules. Superparamagnetic metal oxide nanoparticles entrapped in a layer of dextran and conjugated to a membrane translocating peptide can be internalised by living cells. The cells can be detected by NMR imaging and could be retained on magnetic separation columns (Bioconjugate. Chem. 10 (1999) 186-191). More recent work has shown that semiconductor nanoparticle conjugates coated with a lung-targeting peptide accumulate in the lungs of mice, whereas two other peptides specifically direct the conjugates to blood vessels or lymphatic vessels in tumours (Proc. Natl. Acad. Sci. USA, 99 (2002) 12617-12621). These results suggest that it will be possible to prepare target selective nanoparticle conjugates for disease sensing, in vivo tracking and drug delivery.

Most prior art conjugation methods seek to control the number of probe or other functional molecules bound to a nanoparticle at the level of the final conjugate, when they are present at low concentrations and determination is subject to interference from the particles. This makes it necessary to use indirect methods such as electrophoresis to find out how many binding molecules are present (Nano Lett., 1 (2001) 32-35).

It would be advantageous to provide a nanoparticle conjugate for use in biomolecular assay, and in other applications, for which the number of functional molecules conjugated to the nanoparticles could be determined by more straightforward analytical techniques than has hitherto been the case. It would also be desirable to provide a nanoparticle conjugate which could be determined with greater sensitivity and/or reliability than has been known until now. It would be a further advantage to provide a nanoparticle conjugate which was relatively stable, preferably highly stable, and not readily dissociated. It would also be advantageous to provide a method for producing a nanoparticle conjugate for use in biomolecular assays or other applications in which the numbers and types of molecules conjugated to the particle could be more accurately controlled than has hitherto been the case. It would also be desirable if such a method for producing the nanoparticle conjugates allowed the number and type of molecules conjugated to the particle to be determined more accurately that has been known until now.

It is an object of the present invention to provide such nanoparticle conjugates and methods for making them. One particular object of the invention is to provide nanoparticle conjugates that, when used in a biomolecular assay, are able to resist non-specific binding, will allow fast kinetics, and/or will resist displacement and exchange reactions. Another object of the invention is to provide nanoparticle conjugates with controlled functional affinity. Yet another object of the invention is to provide a nanoparticle conjugate comprising a controlled number of binding molecules for biomolecular assay applications.

Accordingly the invention provides a method for the preparation of nanoparticle conjugates comprising:
a) providing a first reagent comprising a flexible hydrophilic polymer;
b) providing a second reagent comprising at least one functional molecule capable of being substituted into the flexible hydrophilic polymer;
c) providing a third reagent comprising nanoparticles;
d) contacting the first reagent with the second reagent for a period of time and under conditions effective to allow substitution of the at least one functional molecule into the flexible hydrophilic polymer;
e) before, during and/or after step d) providing the flexible hydrophilic polymer with a plurality of conjugation substituents capable, optionally after deprotection, of binding to the nanoparticles to provide an intermediate product comprising the flexible hydrophilic polymer substituted with the at least one functional molecule and a plurality of conjugation substituents capable, optionally after deprotection, of binding to the nanoparticles;
f) if necessary, deprotecting the plurality of conjugation substituents capable of binding to the nanoparticles; and
g) contacting the, if necessary deprotected, intermediate product of step e) with the third reagent for a period of time and under conditions effective to allow binding of the, if necessary deprotected, intermediate product with the nanoparticles to provide the nanoparticle conjugates
   wherein the number of functional molecules conjugated per nanoparticle in the final step is controlled by at least one of:
controlling, by means of suitable selection of reagents and reaction conditions, the number of functional molecules substituted into the flexible hydrophilic polymer in step d);
controlling, by means of suitable selection of reagents and reaction conditions, the number of optionally protected substituents capable of binding to the nanoparticles substituted into the flexible hydrophilic polymer in step e); and
controlling, by means of suitable selection of reagents and reaction conditions, the number of intermediate product molecules binding to the nanoparticles in step g).

The method of the invention allows the preparation of nanoparticle conjugates wherein the number of functional molecules thereon can be controlled according to the end use of the nanoparticle conjugate. The target end product of the method of the invention is a nanoparticle conjugate having a desired number of functional molecules per nanoparticle and the method of the invention permits selection of conditions which yield the desired target end product. If the desired number of functional molecules per nanoparticle is small then the degree of control permitted by the method of the invention is close, even allowing the operator of the method to reliably ensure that, for example, in a sample of nanoparticle conjugates obtained by the method of the invention, the mean number of functional molecules conjugated to each nanoparticle is one. Thus, if the nanoparticle conjugate is intended for use in certain biomolecular assays, the functional molecule may be an assay molecule and the mean number of such assay molecules per nanoparticle conjugate is controlled (probably to a relatively small number) with this end use in mind. However, if the functional molecule is intended for use in certain other assay applications or for use in drug delivery, for example, the mean number of such assay, drug delivery or drug molecules per nanoparticle conjugate is controlled (probably to a relatively large number) with this end use in mind. The degree of control under these circumstances is less close but is still significant in that the operator is able to ensure, for example, that a large mean number of functional molecules conjugate to the nanoparticle. The functional molecules may be directly functional (as assay molecules for example) or their functionality may be indirect in that they may be capable of binding further to other functional molecules.

Control of the mean number of functional molecules per nanoparticle in a given sample is preferably achieved by at least one of:
selecting the relative sizes of the flexible hydrophilic polymer (“size” in this case being a function of at least one of molecular weight, chain length and degree of chain branching) and the nanoparticle to control the number of molecules of flexible hydrophilic polymer, and therefore of optionally deprotected intermediate product, which can be accommodated on the surface of the nanoparticle;
selecting the relative concentrations of the first and second reagents in step d) to control the number of functional molecules substituted into each molecule of flexible hydrophilic polymer; and
selecting the number per molecule of flexible hydrophilic polymer of substituent molecules capable, optionally after deprotection, of binding to the nanoparticles.

Thus, the method of the invention may comprise determining at least approximately the desired mean number of, if necessary deprotected, intermediate product molecules to be bound to each nanoparticle in step g) and selecting the relative size of the flexible hydrophilic polymer and the nanoparticle such that the mean number of, if necessary deprotected, intermediate product molecules which can be accommodated on the surface of each nanoparticle at least approximately matches the desired number. Preferably, especially when the desired number is small (for example less than about 10, less than about 5, from about 1 to 3 or only 1), the number of, if necessary deprotected, intermediate product molecules which can be accommodated on the surface of each nanoparticle at least almost exactly matches the desired number.

The method of the invention may also comprise determining at least approximately the desired number of functional molecules to be substituted into each molecule of flexible hydrophilic polymer in step d) and selecting accordingly the reagent concentrations and reaction conditions in step d).

The method of the invention may also comprise determining at least approximately the desired number of substituent molecules capable, optionally after deprotection, of binding to the nanoparticles to be substituted to each molecule of flexible hydrophilic polymer in step e) and selecting accordingly the reagent concentrations and reaction conditions in step e).

Preferably the relative sizes of the flexible hydrophilic polymer and the nanoparticle are selected to be effective to allow binding in step g) of a controlled number of the, if necessary deprotected, intermediate product molecules with the nanoparticles.

Also provided in accordance with the invention is a method for the preparation of a nanoparticle conjugate comprising:
i. providing a first reagent comprising a flexible hydrophilic polymer having a plurality of at least one type of conjugation substituent capable, optionally after deprotection, of binding to a nanoparticle;
ii. providing a second reagent comprising at least one functional molecule suitable for binding to target molecules, optionally in a biomolecular assay, and capable of being substituted into the flexible hydrophilic polymer;
iii. providing a third reagent comprising nanoparticles capable of binding to the conjugation substituents of the flexible hydrophilic polymer;
iv. contacting the first reagent with the second reagent for a period of time and under conditions effective to allow binding of the functional molecules to the flexible hydrophilic polymer and provide an intermediate product comprising the flexible hydrophilic polymer substituted with the at least one functional molecule; and
v. contacting the intermediate product of step iv) with the third reagent for a period of time and under conditions effective to allow binding of the intermediate product with the nanoparticles to provide the nanoparticle conjugate.

Because the number of functional molecules binding to each molecule of flexible hydrophilic polymer can be closely controlled (by selecting the respective concentrations of the first and second reagents, for example), and because the number of intermediate product molecules conjugating with the nanoparticles can be closely controlled (by selecting the respective sizes of the flexible hydrophilic polymer and the nanoparticles and in some cases controlling the respective concentrations of the intermediate product and the third reagent, for example) the method of the invention allows the production of a nanoparticle conjugate comprising a nanoparticle and a flexible hydrophilic polymer bound to the nanoparticle, the flexible hydrophilic polymer (and hence the nanoparticle) being substituted with a known mean number of functional molecules per nanoparticle conjugate.

Accordingly the invention provides a method for conjugating one or more functional molecules to a nanoparticle. More specifically the invention in some cases concerns a method for substituting known mean numbers of one or more functional molecules into a flexible hydrophilic polymer that is also substituted with conjugation substitutents having chemical groups that are capable of binding to a nanoparticle, and a method for conjugating a known number of substituted polymer molecules to a nanoparticle. The invention accordingly provides a method for producing nanoparticle conjugates having a number of functional molecules that is at least approximately known even without analytical determination of the nanoparticle conjugate after it has been prepared.

The invention also provides a method for producing a nanoparticle conjugate comprising:
I. providing a nanoparticle having a surface area x;
II. providing a flexible hydrophilic polymer having a chain length and degree of branching such that a molecule of the polymer has the capacity, when suitably conformed, to envelop a surface area x/y;
III. substituting into the polymer a plurality of conjugation substituents capable of binding to the nanoparticle and at least one functional substituent capable of imparting a biomolecular or other function to the nanoparticle conjugate; and
IV. conjugating approximately y molecules of the substituted polymer to the nanoparticle via the said plurality of conjugation substituents;
   wherein the flexible hydrophilic polymer is selected with regard to the variable y to provide a nanoparticle conjugate having an at least approximately predetermined number of flexible hydrophilic polymer molecules per nanoparticle. In one preferred application of this method y=x and the nanoparticle conjugate is for use in, for example, reagent limited biomolecular assays and/or DNA expression analysis. In other preferred applications of this method y is greater than, in some cases considerably greater than, x and the nanoparticle conjugate is for use in for example reagent excess biomolecular assays and drug delivery.

The sensitivity of nanoparticle-based biomolecular assays is partly dependent on their functional affinity (number and affinity of assay binding sites per nanoparticle) and an aspect of this invention is to provide a method for exercising control over the functional affinity of nanoparticle conjugates.

In one preferred method of the invention the plurality of substituents capable of binding to a nanoparticle comprise mercapto (—SH) groups or alternatively either disulphide (—S—S—) or thioester (—COS—) groups that can be deprotected to provide ultimately the same conjugation as would be derived from mercapto groups. As mercapto groups form even more stable conjugates with certain types of nanoparticle than most other chemical groups (amino —NH₂ groups, for example), it is another aspect of the invention to provide a method for preparing stable nanoparticle conjugates by multivalent conjugation of mercapto-substituted flexible hydrophilic polymers, mercaptodextrans for example, to nanoparticles, preferably in a manner which controls the number of molecules conjugated to each nanoparticle.

Accordingly, the invention provides a nanoparticle conjugate comprising a nanoparticle conjugated to a functionalised flexible hydrophilic polymer via a plurality of mercapto groups. The invention also provides methods for producing such nanoparticles, as hereinbefore described.

In effect the method of the invention enables the synthesis of the entire surface of the nanoparticle conjugate before its formation by conjugation. This has the significant advantage that if the surface is constructed at high concentration, the number of functional molecules substituted into the surface (before conjugation to the surface of the nanoparticle) can be determined directly, and any purification steps can be carried out using conventional techniques that give a high yield.

The flexible hydrophilic polymer is preferably selected from polysaccharides, polyethylene glycols, polyvinyl alcohols, polyacrylic acids, polyacrylamides, polyamides (including polyamino acids), polycarboxylated polymers (including polyamino acids) and pseuodopolyamino acids. Examples of suitable polysaccharides include natural polysaccharides such as dextran, fucoidan, arabinogalactan, chondroitin and its sulfates, dermatan, heparin, heparitin, hyaluronic acid, keratan, polygalacturonic acid, polyglucoronic acid, polymannuronic acid, inulin, polylactose, polyactosamine, polyinosinic acid, polysucrose, amylose, amylopectin, glycogen, glucan, nigeran, pullulan, irisin, asparagosin, sinistrin, tricitin, critesin, graminin, sitosin, lichenin, isolichenan, galactan, galactocaolose, luteose, mannans, mannocarolose, pustulan, laminarin, xanthene, xylan and copolymers, araboxylan, arabinogalactan, araban, laevans (fructosans), teichinic acid, guaran, carubin, alfalfa, glucomannans, galactoglucomannnans, phosphomannans, fucans, pectins, cyclo-dextrins, alginic acid, tragacanth and other gums, chitin, chitosan, agar, fucellaran, carrageen, cellulaose, celluronic acid or arabinic acid, Additionally chemically and/or enzymatically produced derivatives of these polymers are claimed. Dextran and derivatives thereof, such as aminodextran, carboxydextran and carboxymethyldextran are particularly preferred.

The plurality of conjugation substituents capable, optionally after deprotection, of binding to nanoparticles may effect such binding chemically, electrostatically, hydrophobically or by a combination thereof. The flexible hydrophilic polymer is preferably provided with pendant substituents with such capability. Such substituents preferably comprise a conjugation group (for conjugation to the nanoparticle) selected from sulphides (—S—), asymmetrical or symmetrical disulphides (—S—S—), selenides (—Se—), diselenides (—Se—Se—), mercapto (thiol, sulphydryl, —SH), nitrile (—CN), isonitrile, nitro (—NO₂), amino (NH₂), selenol (—SeH), trivalent phosphorous compounds, isothiocyanate, xanthate, thiocarbamate, phosphine, thioacid (—COSH) or dithioacid (—CSSH) and thioester (—COS—). Particularly preferred conjugation group in this respect include mercapto (thiol, sulphydryl, —SH) and disulphide (—S—S—).

The number, per molecule of flexible hydrophilic polymer, of substituents capable, optionally after deprotection, of binding to the nanoparticles is greater than one, preferably greater than two, more preferably greater than about three, still more preferably greater than about five, most preferably greater than about ten.

The functional molecules may, for example, find applications in biomolecular assays, as ligands for targeting biochemical receptors, or as therapeutic or pharmacological agents. Examples of suitable functional molecules include chelating agents, antigens, haptens, natural or synthetic peptides, natural or synthetic proteins, protein A, protein G, biotin, avidin, streptavidin, antibodies including monoclonal and polyclonal antibodies, Fab′ fragments, Fab fragments, enzymes enzyme cofactors, hormones including steroid, amino acid, peptide and protein hormones, specific carbohydrates, natural and synthetic mono-, oligo- and polysaccharides, gene probes, natural and synthetic polynucleotides and oligonucleotides, lectins, growth factors, vitamins, drugs, hormones, receptor molecules, chimaeric or fusion molecules derived from two or more of these molecules.

The nanoparticle may comprise a metal, for example Au, Ag or a bimetallic composite thereof. Other example of suitable nanoparticle materials include semiconductors such as the sulphides and selenides of Zn, Cd, Pb, Sn, Hg, Al, Ga, In, Ti, Si, Ag, Fe, Fe, Ni and Ca. Preferred semiconductor nanoparticles include CdSe, ZnSe, CdTe, IrP, InAs, PbSe, PbS and CdS. Metal oxide nanoparticles such as iron oxide may also be used. The nanoparticle may have a core-shell structure, in which case the shell may be a metal, semiconductor or metal oxide, and the core may be a metal, semiconductor, metal oxide or metalloid oxide. In some cases the core material may be chosen to render the nanoparticle conjugates responsive to a magnetic field.

The present invention will now be described in more detail, by way of example only, with reference to the following Figures, in which:

FIG. 1 illustrates a schematic representation of a monovalent conjugation method in which oligonucleotides with a terminal mercapto group are conjugated to gold nanoparticles;

FIG. 2 illustrates a comparison between the dissociation of monovalent and multivalent conjugates;

FIG. 3 illustrates a schematic representation of a simple multivalent (divalent) conjugation method based on dihydrolipoic acid (J. Am. Chem. Soc., 122 (2000) 12142-12150). Following conjugation the COOH groups of the conjugate are covalently linked to a protein molecule (avidin);

FIG. 4 illustrates the structural formula of aminotrithiolate that has been used for the multivalent (trivalent) conjugation of antibodies to metallic nanoparticles. This multivalent molecule binds so tightly to silver nanoparticles that aminodextrans, multivalently conjugated to the nanoparticles by a plurality of primary amine groups, are displaced by it (U.S. Pat. No. 5,945,293 (1999));

FIG. 5 illustrates the schematic representation of an entrapment method of conjugation based on mercaptopropyltrimethoxy silane. In step A the mercapto groups bind to the nanoparticle and the alkoxy groups point outwards where they are available for cross-linking to each other and to other silanes in step B. In this representation the other silanes have primary amine groups that can be covalently linked to binding molecules such as antibodies in step C;

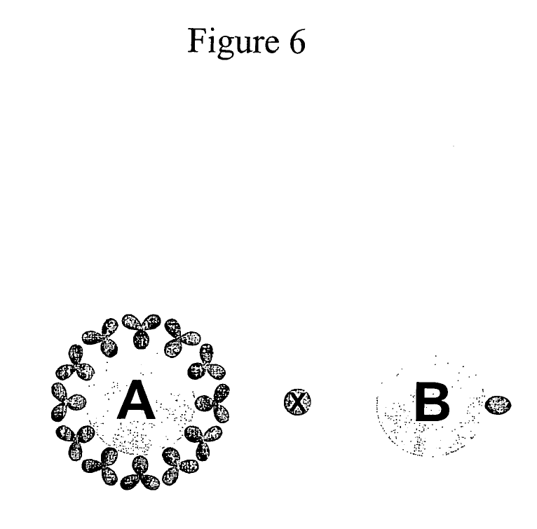

FIG. 6 illustrates that a nanoparticle conjugate has a greater probability of undergoing a collision with an analyte X than a nanoparticle conjugate B because most of the latter's surface is unreactive. Therefore nanoparticle conjugate A has a higher kₐ, and hence a higher functional affinity, than nanoparticle B;

FIG. 7 illustrates that nanoparticle conjugate A is bound to the analyte X at more than site, but nanoparticle conjugate B is only bound at one site. Therefore nanoparticle A has a lower k_{d}, and hence higher functional affinity, than nanoparticle B;

FIG. 8 illustrates that nanoparticle conjugate A has a higher probability of binding to the analyte X and the separation phase than NPC B because most of latter's surface is unreactive. Therefore NPC A has a higher kₐ value for the analyte and the separation phase than NPC B. NPC A may also be able to bind to more than one site on the separation phase, but NPC can only bind to one site. Therefore NPC A may also have a lower value of K_{d} than NPC B;

FIG. 9 illustrates that NPC a has a higher probability of binding to the separation phase than NPC B. NPC A may also be able to bind to more than one site on the separation phase, but NPC B can only bind to one site. When the latter happens NPC A has a higher functional affinity for the separation phase than for the analyte, but NPC B has a similar functional affinity for the separation phase and the analyte.

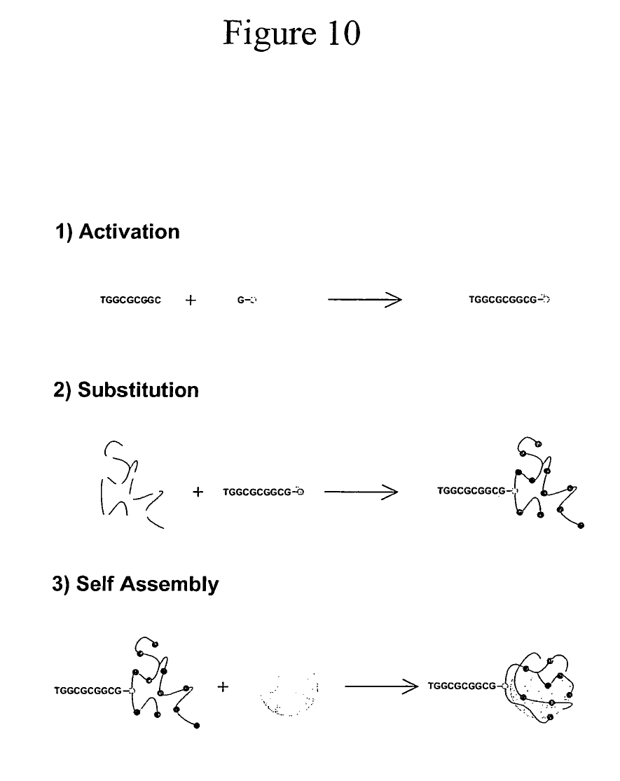

FIG. 10 is a schematic representation of the method used to conjugate PDP dextran linked probe molecules to NPs. Key: 1) the probe molecule (an oligonucleotide in this example) is activated; 2) the probe molecule and PDP are linked to dextran; 3) the dextran is conjugated to the NP by a plurality of dative covalent bonds;

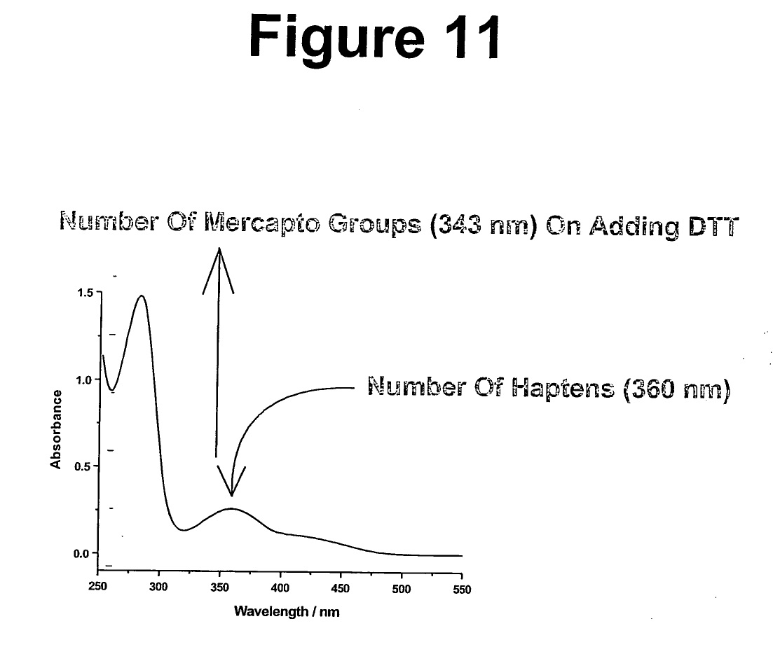

FIG. 11 is a graphical representation of the UV/vis Spectrum of protected mercaptodextran substituted with DNP haptens. The number of DNP haptens can be determined from the absorbance at 360 nm and the number of mercapto groups from the increase in absorbance at 343 nm when DTT is added;

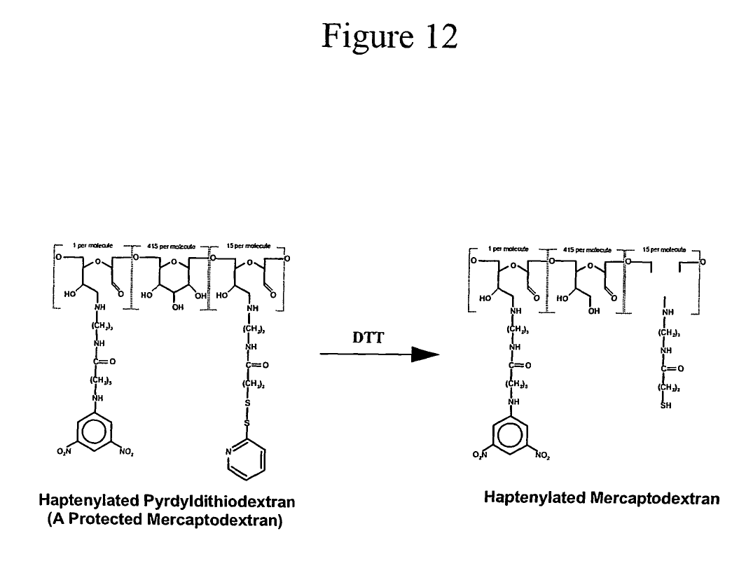

FIG. 12 illustrates the step of deprotection of haptenylated mercaptodextran molecule with DTT (before conjugation to nanoparticles the mercaptodextran is purified by gel-exclusion chromatography);

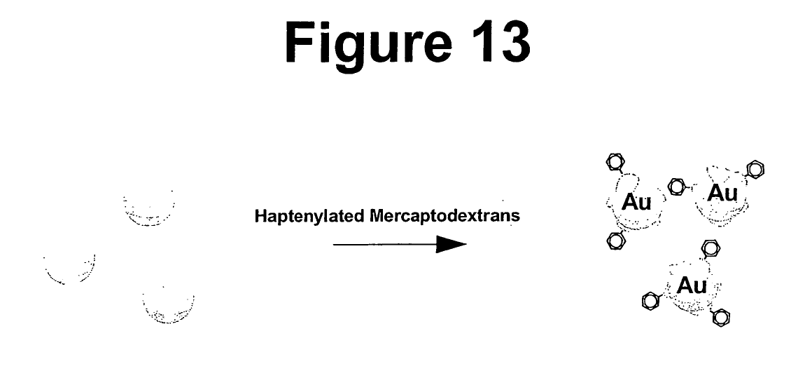

FIG. 13 illustrates a schematic representation of the self-assembly of haptenylated mercaptodextrans to gold nanoparticles;

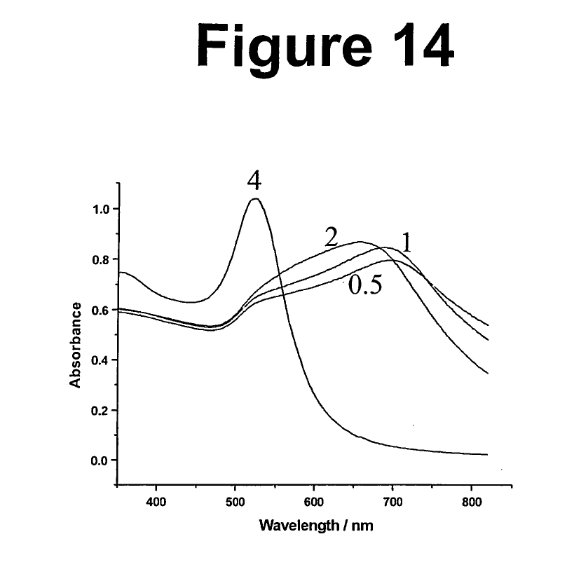

FIG. 14 is a graphical representation of the UV/vis spectra showing the effect of conjugating different numbers of haptenylated mercaptodextrans to gold nanoparticles. The numbers on the spectra correspond to the number of dextran molecules per particle. When there are insufficient dextrans, the particles flocculate on addition of PBS as indicated by the decrease in absorbance at 520 nm;

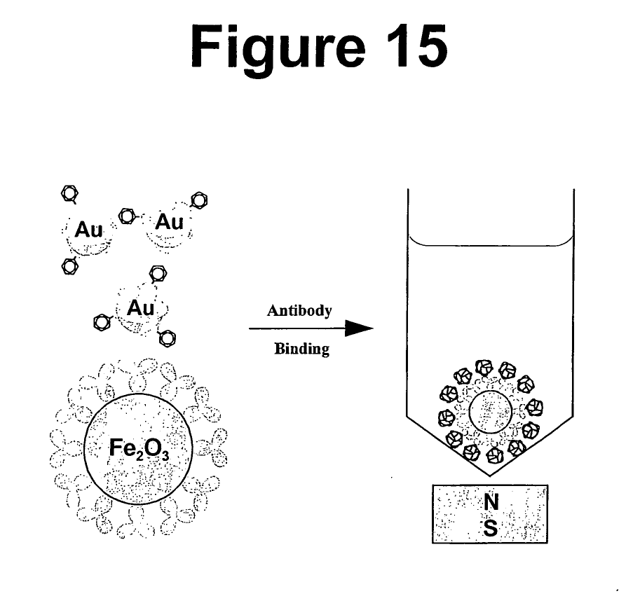

FIG. 15 illustrates a schematic summary of a paramagnetic microbead immunoassay for DNP-gold nanoparticle conjugates;

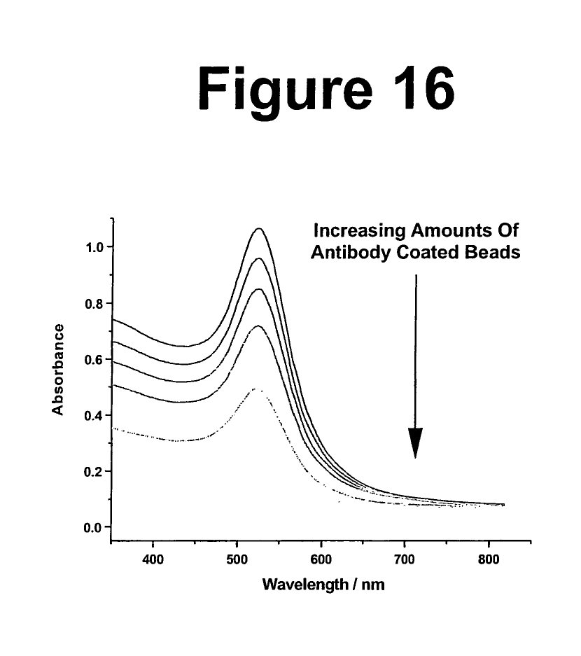

FIG. 16 is a graphical representation of the UV/vis spectra showing the absorbance changes that occur when different amounts of antibodies bound to paramagnetic microbeads are rotated with a nanoparticle conjugate solution;

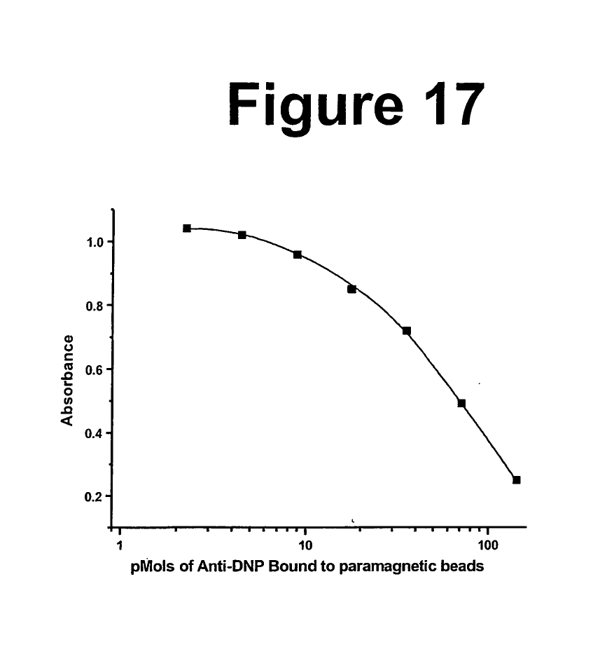

FIG. 17 is a graphical representation of the absorbance at 520 nm for a gold nanoparticle conjugate solution against the amount of antibodies bound to paramagnetic microbeads added and removed by magnetic precipitation;

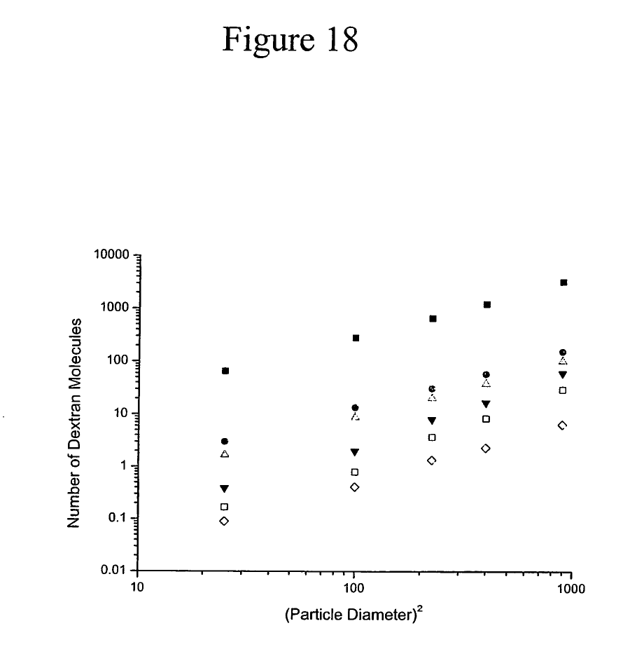

FIG. 18 is graph showing the linear relationship between the minimum numbers of dextrans required to prevent flocculation of GNPs and the squares of the particle diameters. Key: =10 kDa; =40 kDa; =70 kDa; =170 kDa; =500 kDa; =2000 kD;

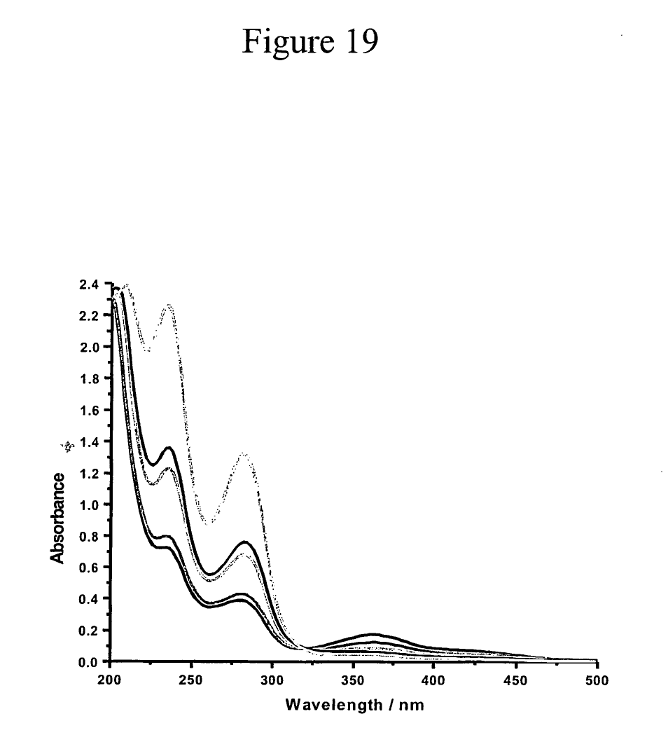

FIG. 19 is a WV/vis spectra of PDP dextrans substituted with different numbers of DNP haptens. The mean number of haptens per molecule of dextran in order of decreasing absorbance at 360 nm (DNP) is: 12, 8.6, 5.9, 4.4 and 1.2;

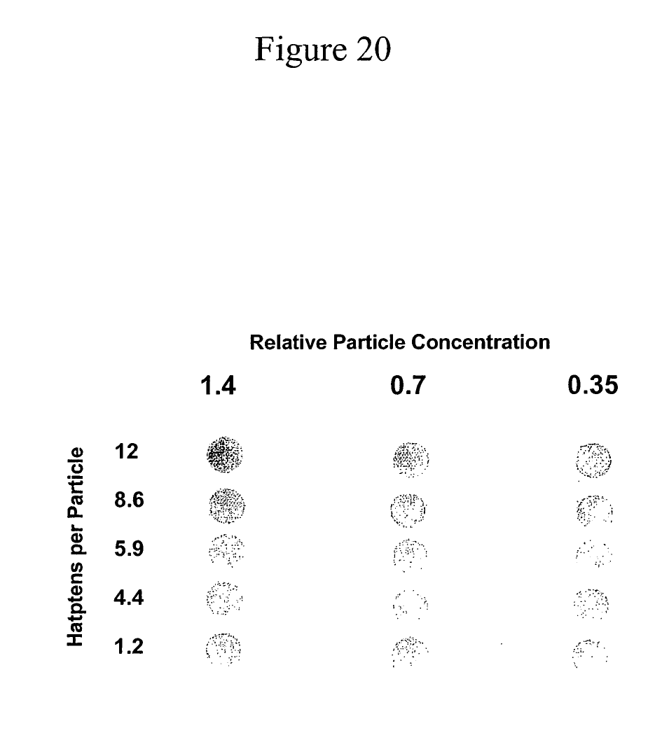

FIG. 20 is a multiwell plate image showing how the amount of GNP conjugate bound to microbeads increases as the number of probe molecules per particle increases. The amount of conjugate bound is proportional to the colour density of the wells;

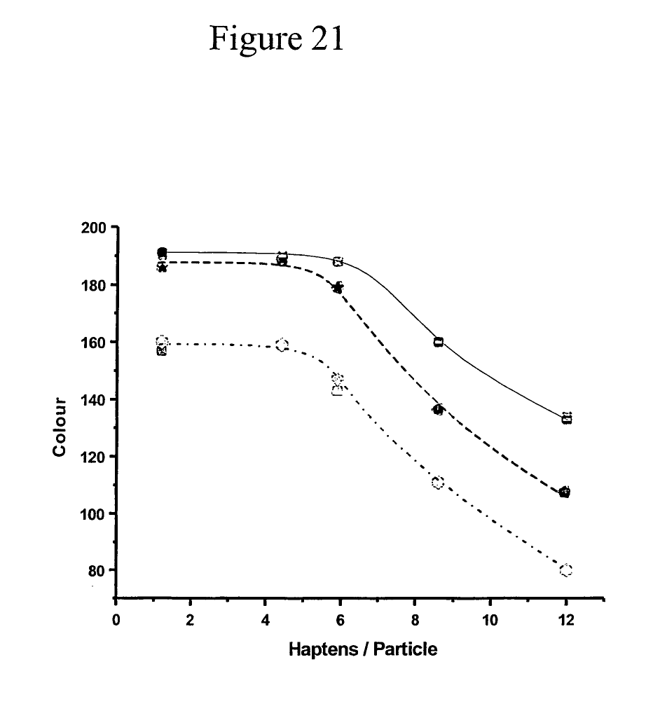

FIG. 21 is a graph showing how the colour density of the microbeads in FIG. 20 increases as the number of probe molecules per particle increases. Key to relative conjugate concentration: 0.35 (solid line); 0.7 (dashed line); 1.4 (chain dot line). Note that on the greyscale of 0-255 high colour density corresponds to low numerical values;

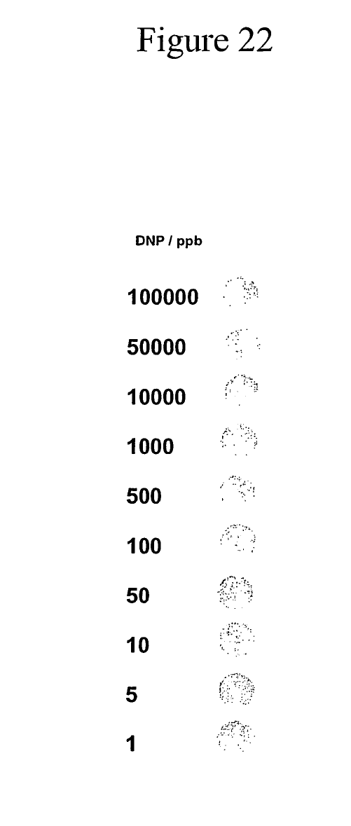

FIG. 22 is a multiwell plate image showing the results of a reagent limited (competitive) immunoassay for DNP;

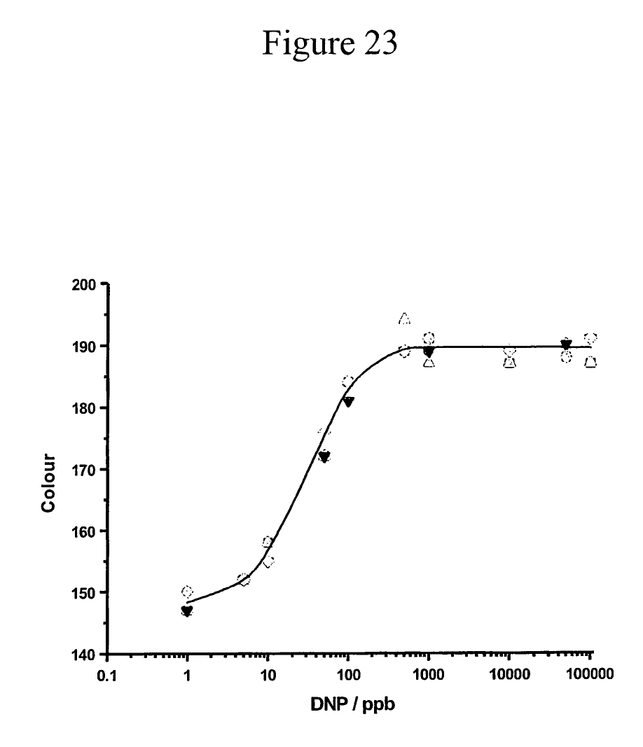

FIG. 23 is a graph showing how the colour density of the microbeads in FIG. 22 increases as the amount of DNP decreases. Note that on the greyscale of 0-255 high colour density corresponds to low numerical values;

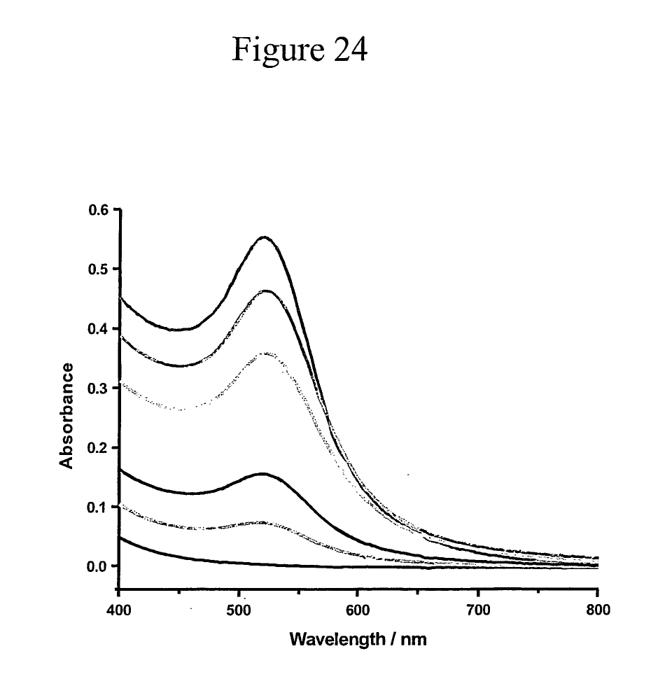

FIG. 24 shows a UV/vis spectra of 10 nm gold nanoparticles stabilized with different amounts of 70 kDa PDP dextran. The numbers of dextran molecules per particle, in order of increasing absorbance, are 0, 4.3, 4.9, 5.2, 5.7 and 7.1;

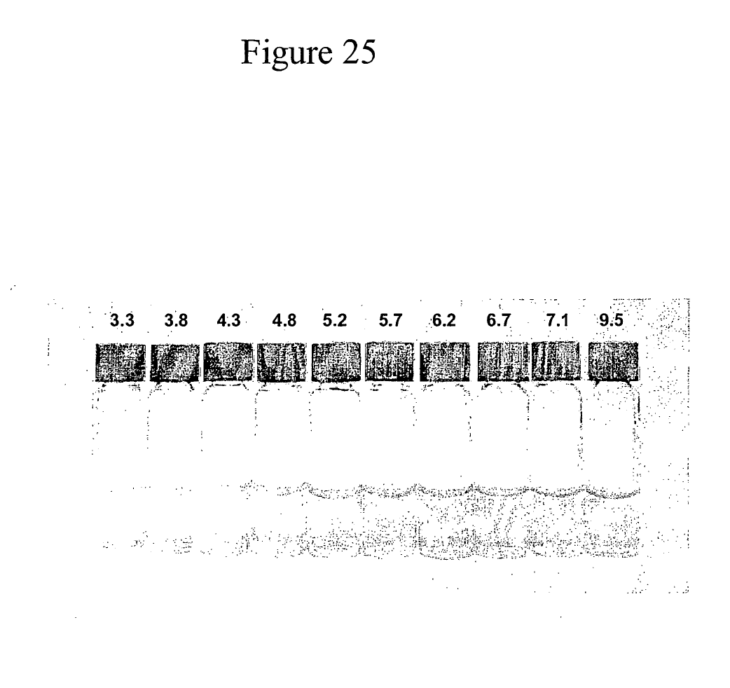

FIG. 25 is an image of 10 nm gold nanoparticles conjugated to different amounts of 70 kDa PDP dextran. The numbers indicate the ratio of dextran molecules to particles;

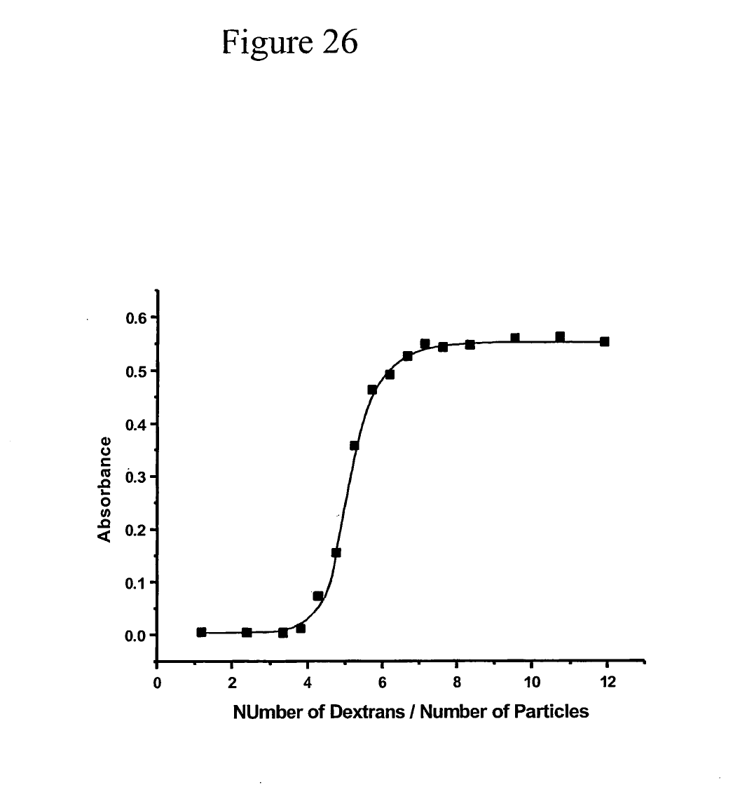

FIG. 26 is a graph showing how the maximum absorbance of gold nanoparticles varies for different ratios of 70 kDa PDP dextran per nanoparticle. The minimum amount required to prevent any flocculation is taken as the lowest ratio that does not lead to a decrease in the maximum absorbance;

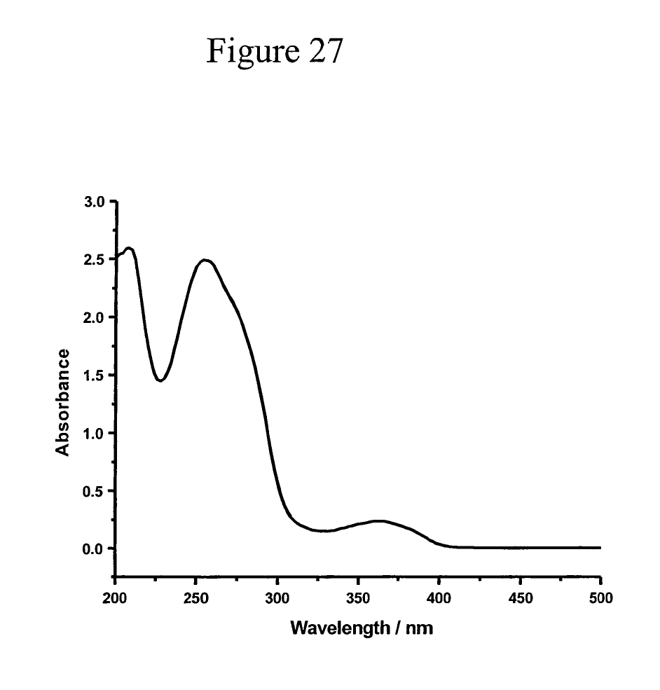

FIG. 27 is a UV/vis spectrum of 70 kDa PDP dextran substituted with 19-mer oligonucleotides. This spectrum was recorded using a quartz cuvette with a 3 mm path length;

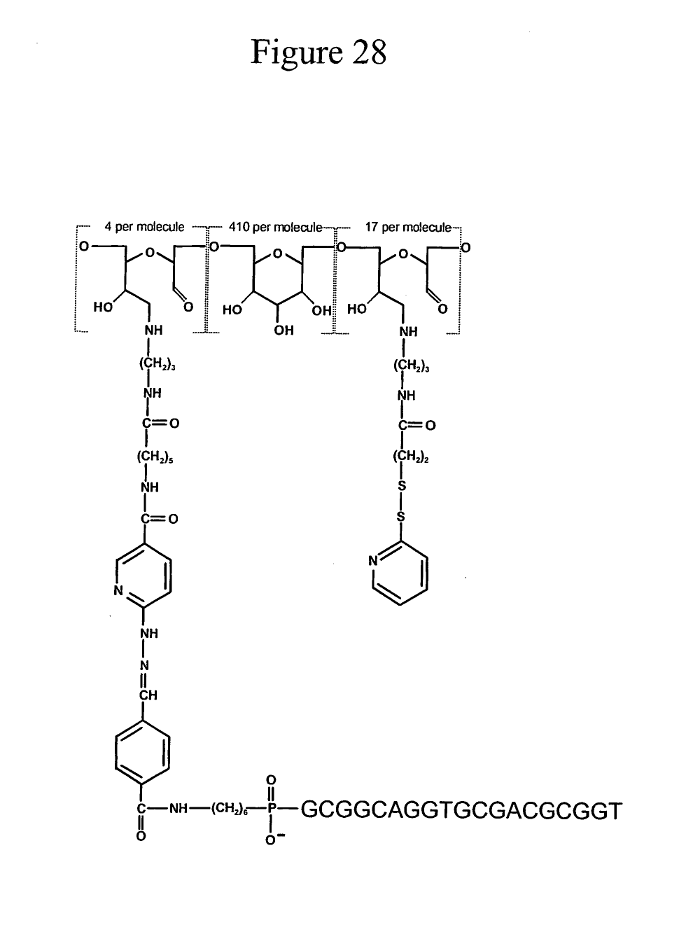

FIG. 28 illustrates the structure of 70 kDa PDP dextran substituted with 19-mer oligonucleotides;

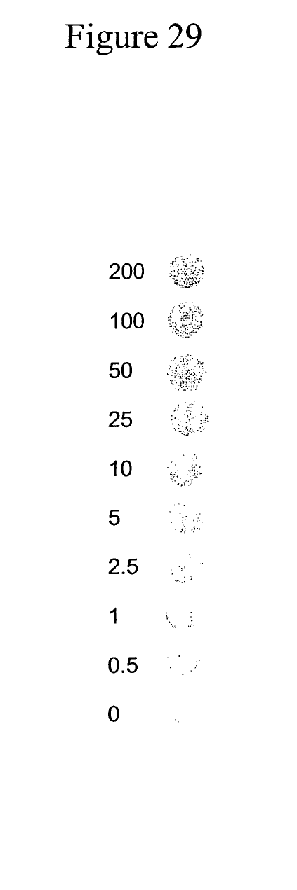

FIG. 29 is an image of a multiwell plate showing oligonucleotide GNP conjugate hybridised to different amounts of complementary oligonucleotides bound to polymer microbeads; amounts of the latter are given in picomols. This image was acquired with an ordinary document scanner;

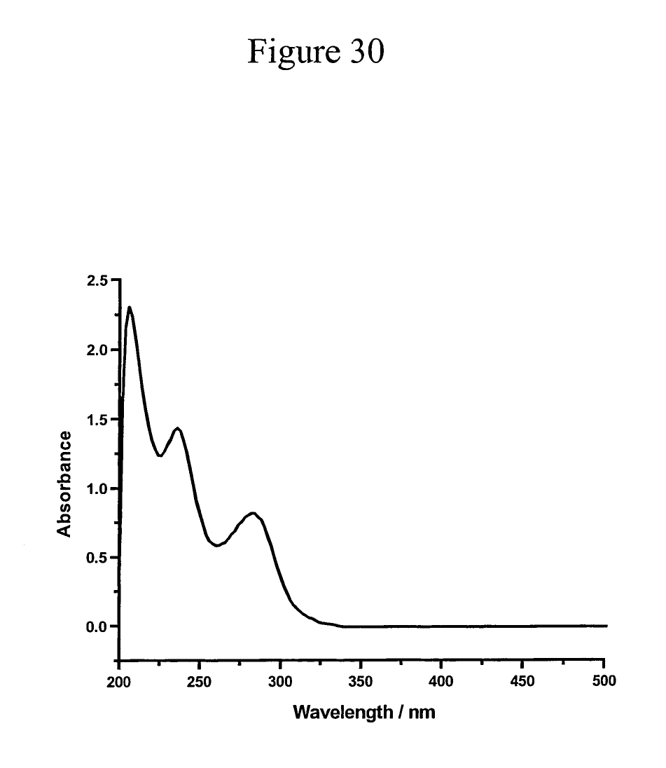

FIG. 30 shows a UV/vis spectrum of 2000 kDa PDP dextran substituted with biotin caproic acid;

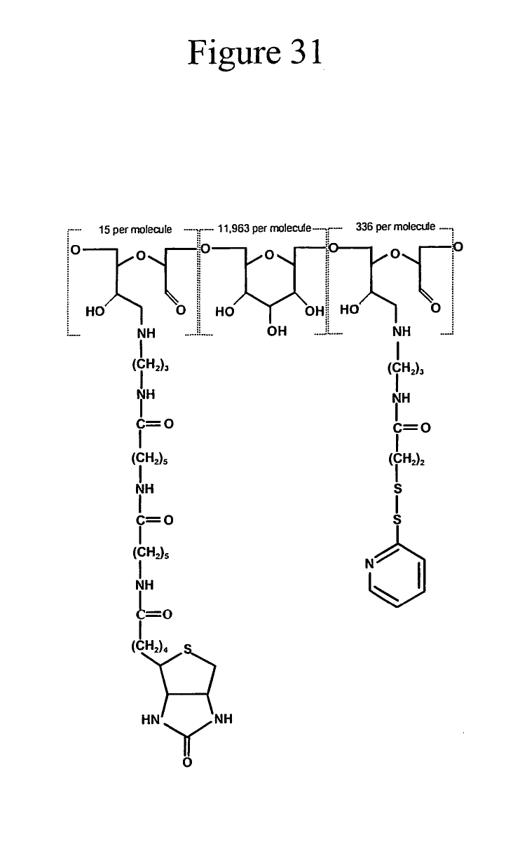

FIG. 31 illustrates the proposed structure of PDP dextran substituted with biotin caproic acid;

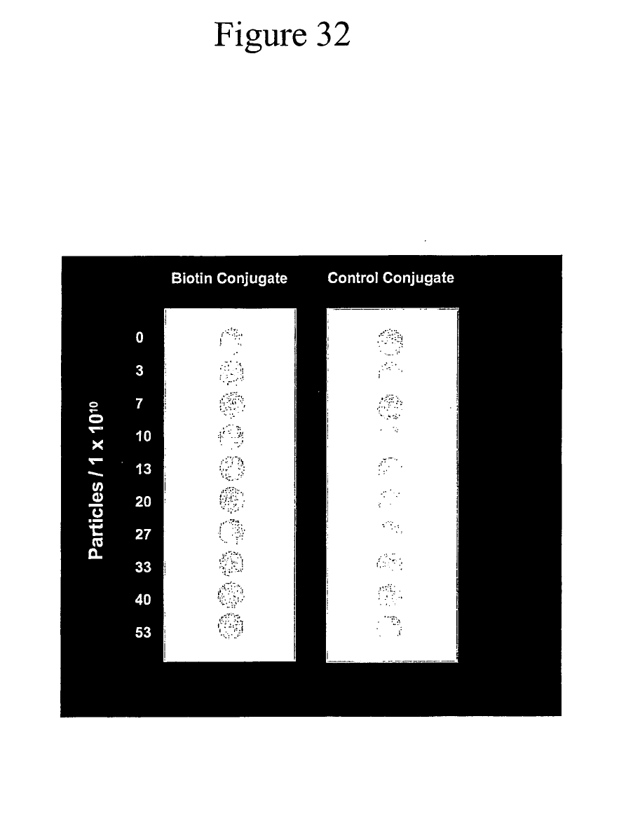

FIG. 32 is an image of a multiwell plate showing different amounts of biotin conjugate bound to streptavidin-coated microbeads. The control image shows a multiwell plate containing beads that were incubated with the same amounts of conjugate that did not have biotin as the probe molecule. This image was acquired with an ordinary document scanner;

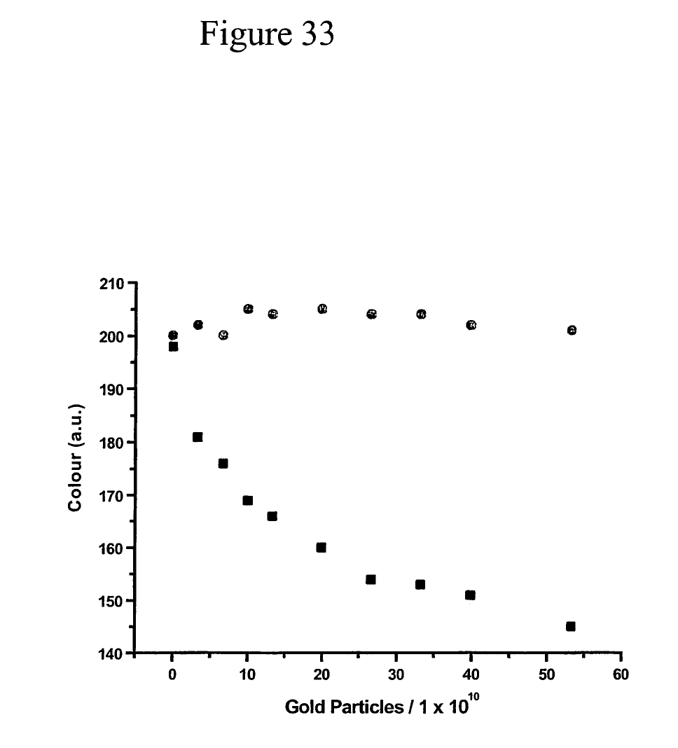

FIG. 33 is a graph of colour density against the amount of GNPs bound to the microbeads in FIG. 32. Key: =biotin conjugate; =conjugate without biotin;

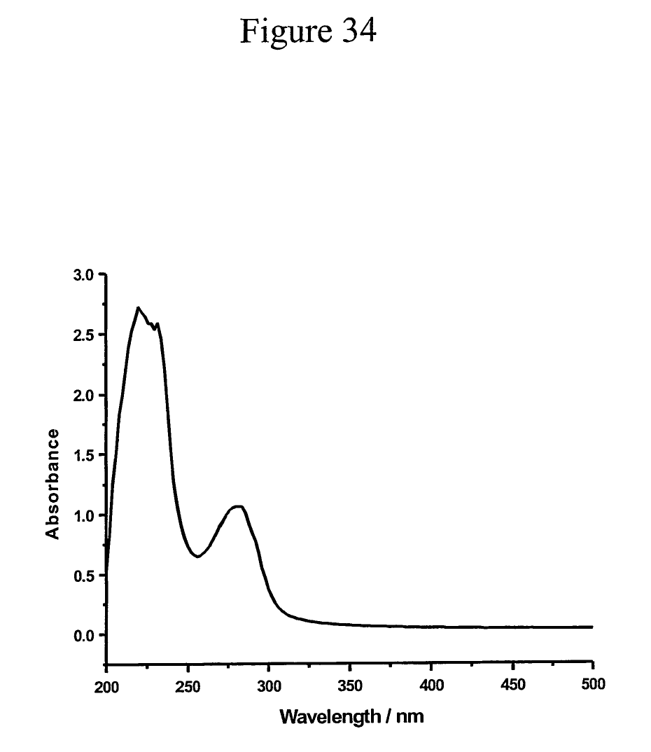

FIG. 34 shows a UV/vis spectrum of antibody PDP dextran. This spectrum was recorded using a quartz cuvette with a 3 mm path length;

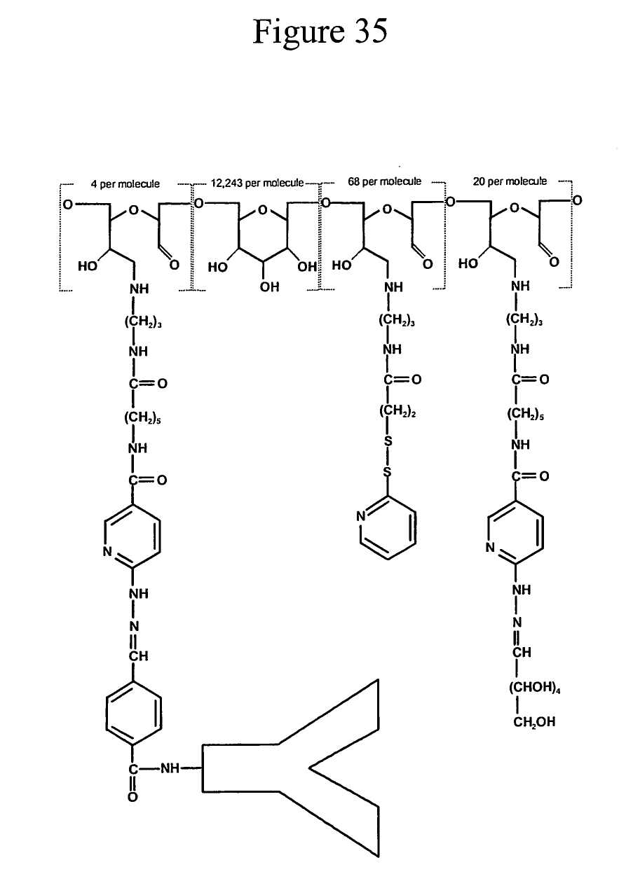

FIG. 35 illustrates the proposed structure of the antibody linked PDP dextran;

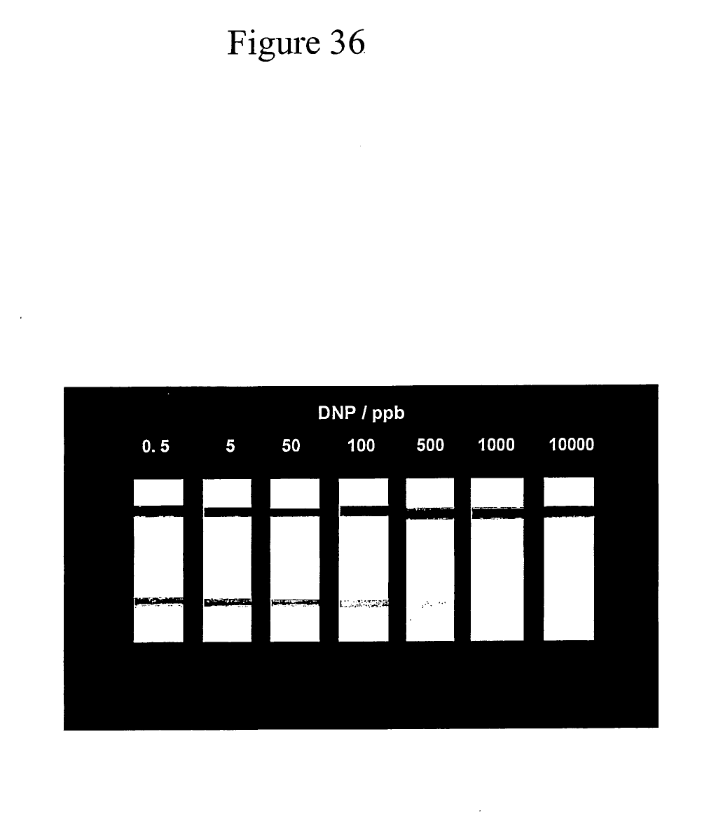

FIG. 36 shows the results of reagent reagent-limited immunoassays for DNP with antibody conjugate on lateral flow devices;

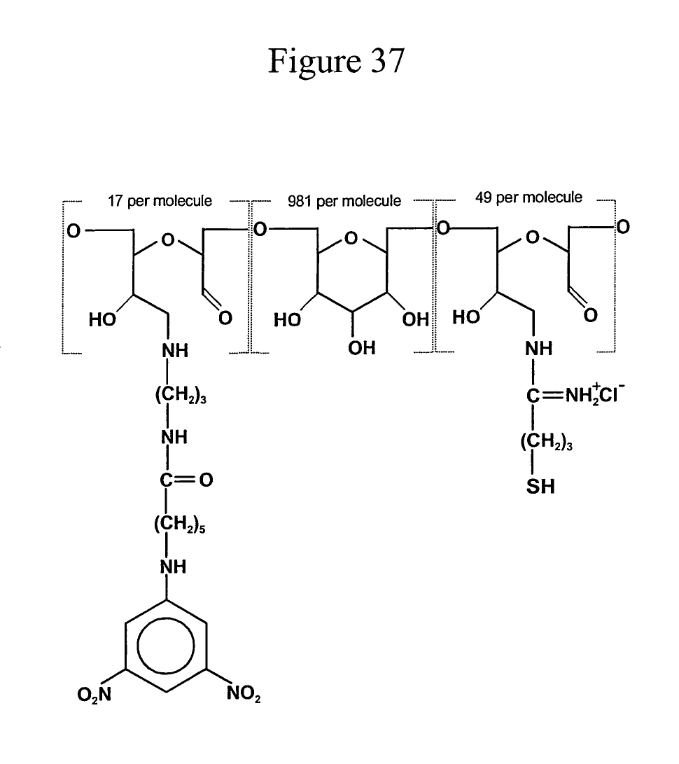

FIG. 37 shows the proposed structure of haptenylated mercapto dextran used to prepare QD conjugates; and

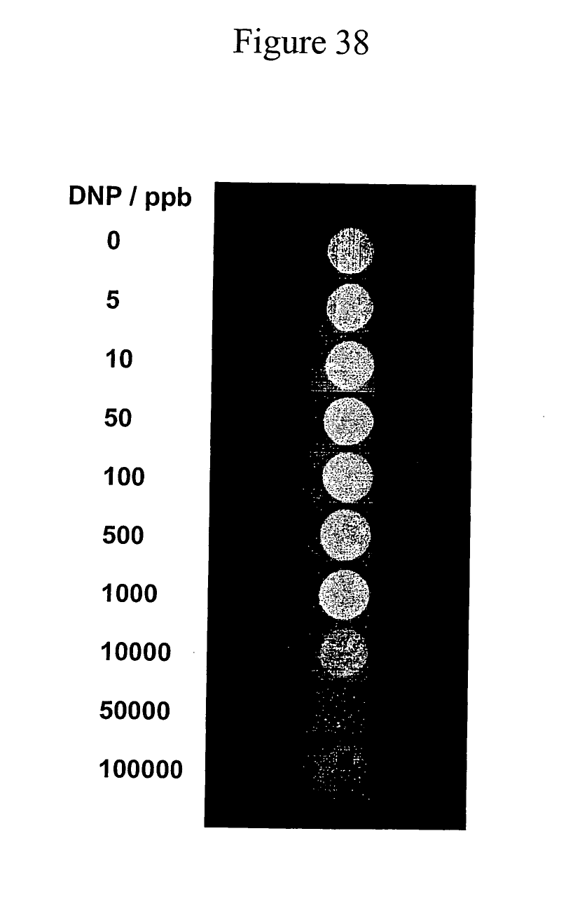

FIG. 38 is an image showing the results of a reagent limited (competitive) immunoassay for DNP with QD DNP conjugate.

FIGS. 1 to 9 have already been described and discussed with reference to the prior art.

In the following discussion, reference is made, for convenience, to nanoparticle conjugates wherein the flexible hydrophilic polymer is a dextran or a dextran derivative and wherein the plurality of conjugation substituents capable of binding to nanoparticles are mercapto substituents, or protected substituents which provide, on deprotection, the same type of conjugation as would be provided by mercapto substituents. However, it should be recognized that other types of flexible hydrophilic polymer and other types of conjugation substituent are contemplated herein and are within the scope of the invention and the ensuing discussion.

The conjugation methods described here can be divided into three main steps (FIG. 10). In the first step a functional molecule that can participate in biomolecular binding reactions is activated. In the second step the activated molecule, and a molecule with a disulphide bond, are substituted into dextran under conditions that allow the number and type of substituents to be accurately determined. In the third step the substituted dextran is conjugated to the NPs by a process of self-assembly, in which the sulphur atoms of the mercapto groups become chemically bound to the particles. The third step is carried out in such a way that the number of substituted dextrans conjugated to each NP is controlled by the relationship between the size (molecular weight) of the dextran and the diameter of the particle.

The invention provides a method (summarized in FIG. 10) for synthesizing a surface polymer with a known and controlled number of functional molecules at high concentration prior to conjugation. This surface polymer is conjugated to the nanoparticles by a process of self-assembly in which the sulphur atoms in a plurality of mercapto groups become chemically bound to the nanoparticles. The number of polymer molecules conjugated to each nanoparticle is determined by the size of the polymer and the size of the nanoparticle. This is an example of a method preparing nanoparticle conjugates, in which a polymer with a known number of functional molecules is conjugated to particles by a plurality of electrostatic, hydrophobic or chemical interactions, such that the number of polymer molecules per particle is determined by the size of the polymer and size of the particle. One advantage of nanoparticles is that they have dimensions that are similar to the molecules that are used in biomolecular assays as shown in Table I:

TABLE I

| Entity | Approximate Dimensions (nm) |
|---|---|
| Glucose | 0.5 |
| Biotin | 0.7 |
| DNA Helix (25 bases) | 8.5 × 2 |
| Antibody (Immunoglobulin G) | 4 |
| Glucose Oxidase | 8 |
| Semiconductor nanoparticles | 2-10 |
| Metallic nanoparticles | <100 |
| Animal Viruses | 22-120 |
| Bacteria | 500-1200 |
| Mitochondrion | 600 |
| Chloroplasts | 5000 |
| Human Cells | 10,000 |

The invention provides for a method of conjugating a known number of molecules that can participate in biomolecular and other applications to nanoparticles. In one such method the molecules are covalently attached to a polysaccharide that is also substituted with a plurality of pendant mercapto groups. The polysaccharide is conjugated to the nanoparticles by a multivalent method in which the sulphur atoms of the mercapto groups are chemically bound to the nanoparticles.

The invention provides in one of its aspects a three-step method for preparing nanoparticle conjugates. In the first step of the method a functional molecule is activated. In the second step of the method a polysaccharide is substituted with a predetermined number of two or more molecules, one of which is a functional molecule and one of which has a mercapto group, or a chemical group that can be converted to a mercapto group. The second step is carried out under conditions that allow the number and type of molecules substituted into the polysaccharide to be accurately determined. In the third step of the method the substituted polysaccharide is conjugated to the nanoparticles by a process of self-assembly in which the sulphur atoms of the mercapto groups become chemically bound to the particles. The second step may be carried out in such a way that the number of substituted polysaccharides conjugated to each nanoparticle is controlled by the relationship between the size of the polysaccharide and the size of the particle.

Described herein is a method for conjugating a known number and type of one or more functional molecules to a nanoparticle (FIG. 10). For the purpose of the invention the term nanoparticle (nanoparticle) refers to particles with diameters of preferably less than about 100 nm. In the second part of the method the said functional molecules are covalently attached to a flexible hydrophilic dextran polymer that is also substituted with mercapto groups or protected mercapto groups. This part of the method is preferably carried out under conditions that allow the number and type of molecules substituted into the polymer to be accurately determined. In the third part of the method the substituted polymer is conjugated to the nanoparticles by a process of self-assembly, in which the sulphur atoms of the mercapto groups are chemically bound to the particles. The third part of the method is carried out in such a way that the number of polymer molecules conjugated to each nanoparticle is controlled by the relationship between dextran size and particle size.

The flexible hydrophilic polymer into which molecules are to be substituted is preferably derivatized with primary amines that can be covalently attached to substituent molecules. The polymer is preferably an aminopolysaccharide and preferably an aminodextran, where the word dextran refers to any branched polysaccharide of D-glucose, regardless of the branch point of the repeating unit; i.e., 1 2, 1 3, 1 4, etc. Aminodextrans are dextrans that have been derivatized with primary amine (NH₂) groups. Methods for preparing aminodextrans include reductive amination of periodate oxidized dextran (Biosens. Bioelectron., 11 (1996) 579-590), reaction of activated dextrans with mono-protected diamines followed by removal of the protecting group (Makromol. Chem., 192 (1991) 673-677), and reaction of excess diaminoalkanes with periodate oxidized dextran (Bioconjugate Chem., 10 (1999) 1090-1106).

In order to produce nanoparticle conjugates that can be used in biomolecular assays and other applications aminodextrans are substituted either directly with molecules that can participate in the said applications, or indirectly with molecules possessing chemical groups that can be linked to molecules that can participate in the said applications. The direct substitution of molecules into aminodextrans is preferably accomplished by activating the molecules that are to be substituted, or derivatives thereof, with a reactive group. Examples of reactive groups are succinimidyl or sulfosuccinimidyl esters, isothiocyanates and sulfonyl chlorides. Examples of activated molecules are succinimidyl 6-(biotinamido)hexanoate, fluorescein-5(6)-carboxamido-caproic acid NHS and atrazine NHS ester (Biosens. Bioelectron, 12 (1997) 277-286). The indirect substitution of molecules into the aminodextrans is accomplished by activating the primary amines with a bifunctional reagent. Examples of bifunctional reagents are succinimidyl hydraziniumnicotinate and related aromatic hydrazines, C6-succinimidyl 4-hydrazinonicotinate acetone hydrazone and related aromatic hydrazones, succinimidyl 4-formylbenzoate and related aromatic aldehydes, suberic acid bis (NHS ester), 6-(iodoacetamide)caproic acid NHS ester, succinimidyl-4-(N-maleimidomethyl)cyclohexane-1-carboxylate (SMCC), succinimidyl-4-(N-maleimidomethyl)cyclohexane-1-carboxylate (SMCC), 3-maleimidobenzoic acid NHS (MBS), γ-maleimidobutyric acid NHS (GMBS), ε-maleimidocaproic acid NHS (EMCS) and β-maleimidopropionic acid NHS (BMPS).

Although a number of methods for substituting molecules into dextrans have been described (Bioconjugate Techniques, Academic Press (1996) pp. 618-629; WO 93/01498; and WO 90/05303), not all of them are suitable for preparing NP conjugates. Dithiol chemistry is not suitable because the bonds are broken on contact with metal and semiconductor surfaces. The thioether bonds formed by maleimido/thiol reactions also form bonds with GNPs, which may interfere with bimolecular reactions (J. Mater. Chem. 11 (2001) 1919-1923). Amide bonds are stable, and we have used NHS ester chemistry (Bioconjugation, Macmillan, (1998) 254-261 and Bioconjugate Techniques, Academic Press (1996) pp. 139-140), to substitute the low molecular weight molecules into dextrans. NHS ester chemistry is less suitable for linking biological molecules to dextrans because the activated molecules are unstable in aqueous solution. In order to overcome this problem we have used NHS ester chemistry to substitute hydrazide groups into dextrans. The reaction of a hydrazide with an aldehyde results in the formation of a hydrazone bond. Acyl hydrazones must be reduced to prevent hydrolysis, but strong reductants may damage probe molecules while the mild reductant sodium cyanoborohydride is extremely toxic. We have avoided these problems by using 6-hydrazinonicotinamides, which form stable hydrazone bonds that do not require reduction (Bioconjugate Chem. 2 (1991) 333-336 and Bioconjugate. Chem. 10 (1999) 808-814). A further advantage of this choice is that activation and substitution are both accompanied by well-characterized changes in the UV/vis spectrum, which allows the products to be characterized prior to conjugation. By using a combination of NHS ester and 6-hydrazinonicotinamide chemistry we have substituted a range of low MW molecules, oligonucleotides and proteins into dextrans. Those familiar with bioconjugate chemistry will appreciate that this range can easily be extended to include a variety of other molecules including hormones, peptides, enzymes, streptavidin, antibody fragments, lectins and receptor-specific probes.

For the purpose of conjugating the substituted dextran molecules to nanoparticles in the third part of the method, the aminodextrans are also substituted with mercapto (thiol, sulphydryl, —SH) groups, or chemical groups that can be converted to mercapto groups by removal of a protecting group. Mercaptodextrans have been prepared previously for use as chelating agents (Acta Pharmacologica. Sinica, 11 (1990) 363-367) and for coating macroscopic gold surfaces with dextrans (Biomaterials, 21 (2000) 957-966 and Analyst, 128 (2003) 480-485). Mercapto groups can be substituted into aminodextrans by reaction with reagents such as 2-iminothiolane. Chemical groups that can be converted to a mercapto groups by removal of a protecting group can be substituted into aminodextrans with reagents such as N-succinimidyl-3-(2-pyridyldithio)propionate (SPDP), N-hydroxysuccinimide s-acetylthioacetic acid (SATA) and S-acetylmercaptosuccinic anhydride (SAMSA). SPDP can be deprotected with dithiothreitol (DTT) or tris-(2-carboxyethyl)phosphine (TCEP), and SATA and SAMSA can be deprotected with 50 mM hydroxylamine. In some manifestations of the invention it is important that SATA and SAMSA (unlike SPDP) do not react with mercapto groups prior to deprotection. Further examples of bifunctional reagents are described in texts such as The Pierce Handbook and Chemistry Of Protein Conjugation And Cross-Linking [Wong, S. S.] CRC Press, Inc., Boca Raton, Fla., (1991).

The substitution of molecules into aminodextrans is preferably carried out under conditions that allow the number and type of the said molecules to be determined accurately. For this purpose it is advantageous if the molecules are substituted into the aminodextrans at relatively high concentrations such that the degree of substitution can be accurately determined by simple methods such as UV/vis spectroscopy. For the purpose of accurate determination it is also advantageous if the polymer is prepared in the absence of interference from the nanoparticles. Preparation at relatively high concentration also facilitates purification and increases the yield of the substituted dextran product.

In the second part of the method the substituted mercaptodextrans prepared in the first part of the method are conjugated to the nanoparticles. In the context of the invention nanoparticle may refer to a metal, metal oxide or semiconductor particle that is preferably less than about 100 nm in diameter. Conjugation is carried out by a process of self-assembly in which the sulphur atoms of mercapto groups or protected disulphide bonds in the dextran become chemically bound to the nanoparticle. When the dextran is substituted with a protected disulphide bond mercapto groups may be generated by spontaneous fission of the said bond on contact with the nanoparticle (J. Am. Chem. Soc., 124 (2002) 5811-5821) or by chemical fission of the disulphide with a reducing agent such as DTT or TCEP or a nucleophile such as hydroxylamine (Biochem. J., 173 (1978) 723-737; Anal. Biochem., 132 (1983) 68-73). When the mercapto groups are generated by chemical fission of a disulphide bonds the substituted dextran may be purified by gel-exclusion chromatography prior to conjugation in order to remove small molecules that are capable of binding to the nanoparticles.

Another advantage of the invention is that the number and type of molecules conjugated to each nanoparticle may be finely controlled. When a fixed number of nanoparticles are titrated with different amounts of a given mercaptodextran, the minimum number of mercaptodextran molecules required to stabilize the nanoparticles depends on the size of the mercaptodextran molecules and the size of nanoparticles. The size of a mercaptodextran molecule determines the extent to which it can cover the surface area of a nanoparticle; size is related to the molecular weight (MW) of the dextran, but other factors such as the amount of polymer branching, the number and type of the functional molecules and the number of mercapto groups are also involved. If the size of the nanoparticle is appropriately matched to the size of the mercaptodextran the number of mercaptodextran molecules that can be accommodated by each nanoparticle is limited to one. When this happens the number of functional molecules conjugated to each nanoparticle is equal to the number of functional molecules in one molecule of the mercaptodextran. When the nanoparticle can accommodate more than one mercaptodextran molecule the number of molecules conjugated to each particle will be a multiple of the number of functional molecules in one molecule of the mercaptodextran.

The following Examples further illustrate the invention:

### EXAMPLE 1

This Example describes the production of protected mercaptodextrans (PDP dextrans) with a known number of haptens. To prepare protected mercaptodextrans with a mean of about one hapten per molecule 6(2,4-dinitrophenylamino)-1-aminohexanoic acid [N-hydroxysuccinimide ester] (DNPAH-NHS) and SPDP were dissolved in dry DMSO to final concentrations of 7.2 mM and 0.116 M respectively. This solution (0.2 ml) was added, dropwise with stirring to 10 mg of aminodextran (MW 70,000; 16.2 primary amines per molecule as determined by the phthalaldehyde method described in: Makromol. Chem., 192 (1991) 673-677) dissolved in 5 ml of 50 mM (pH unadjusted) bicarbonate solution. After standing overnight at 4° C. in darkness, the solution was loaded onto a PD-10 column (Sephadex G-25, from Amersham Pharmacia Biotech) and eluted with tris buffered saline (TBS). A UV/Vis spectrum of the haptenylated dextran eluted form the PD-10 column is shown in FIG. 11. The spectrum corresponds closely to the spectrum of dinitrophenol and 2-pyridyldisulphide (PDP), with a small additional amount of absorbance at short wavelengths due to scattering by the dextran. From the absorbance at 360 nm (1.74×10⁴ M⁻¹ cm⁻¹; Anal. Biochem. 177 (1989) 392-395) and the increase in absorbance at 343 nm (8.08×10³ M⁻¹ cm⁻¹; Biochem. J., 173 (1978) 723-737) on adding dithiothreitol (DTT) the ratio of dinitrophenyl (DNP) hapten to protected mercapto groups was determined to be 16:1; this corresponds closely to one hapten per molecule of dextran. The proposed structure of the haptenylated dextran is shown in FIG. 12. Protected mercaptodextrans substituted with reactive derivatives of molecules other than DNP can be synthesized by similar methods, and by extension known amounts of more than two molecules (e.g. DNP, biotin and PDP) can also be substituted into aminodextrans.

### EXAMPLE 2

This Example describes the production of protected mercaptodextrans with a known number of proteins. Where the protein that is to be conjugated does not contain a suitable mercapto group it is thiolated with 2-imminothiolane, or with SPDP followed by reductive deprotection of the disulphide and gel-exclusion chromatography. The latter is preferred because it minimizes the possibility of disulphide crosslinking and allows the average number of mercapto groups substituted into each protein molecule to be determined from the amount of pyridinedithione chromophore released on reduction with DTT. Introduction of a mercapto groups into antibodies is carried out by adding 75 μl of 13.5 mM of 2-imminothiolane [HCl salt] in PBS to a stirred solution of 10 mg of antibody (IgG) in 2 ml of PBS. After slant rotating for 1 hour at room temperature the thiolated antibody is purified by dialysis against PBS, or by gel-exclusion chromatography on Sephadex G-25. Fab′ fragments which have a single antigenic binding site are particularly useful in the context of the invention because they allow the number of binding sites per nanoparticle conjugate to be limited to one. Fab′ fragments are prepared by proteolytic cleavage of antibodies with pepsin followed by reduction with 2-mercaptoethylamine (J. Biochem. 92(1982)1413-1424). They contain a single mercapto group, which is remote from the single antigen binding site, and therefore it is unnecessary to introduce a mercapto group chemically. Protected mercaptodextrans with one maleimide group per molecule of dextran are prepared by a method similar to Method 1, except that SMCC is used in place of DNPAH-NHS, and SATA is used in place of SPDP. The ratio of mercapto groups to maleimide groups in the dextran is determined by reacting the protected mercaptodextran with deprotected fluorescein SAMSA (Molecular Probes, Eugene, Oreg., USA) and reacting the deprotected mercaptodextran with 5,5′-dithiobis-(2-nitrobenzoic acid) (DNTB, Eliman's reagent; Anal. Biochem.; 101 (1980) 442-448). The number of maleimide groups is determined from the fluorescence at 520 nm and the number of mercapto groups is determined from the absorbance of the 410 nm (1.36×10⁴ M⁻¹ cm⁻¹). In order to ensure that there is only one protein molecule per molecule of dextran the latter is added dropwise to an excess of thiolated protein (5× the molarity of maleimides in the dextran) in pH 6.0, 0.1 M phosphate buffer and slant rotated for 30 minutes. At the end of this time the dextran protein conjugates are purified on Sepharose 4B. Protected mercaptodextrans with a known number of oligonucleotides are prepared by similar methods except that oligonucleotides with a terminal mercapto group are used instead of thiolated proteins.

### EXAMPLE 3

This Example describes the production of gold nanoparticle conjugates with a known number of haptens. The process of self-assembly used to conjugate substituted mercaptodextrans to nanoparticles is shown schematically in FIG. 13. Protected mercaptodextrans (PDP dextrans) are deprotected by reduction with DTT followed by gel filtration on Sephadex G-25. A known amount of nanoparticles is mixed with different amounts of deprotected mercaptodextran dissolved in water and then phosphate buffered sodium chloride is added to give a final concentration equivalent to PBS (15 mM Na Phosphate, 0.15 M NaCl). When the amount of dextran was too low to stabilize the particles they flocculated on addition of PBS as shown in FIG. 14. The minimum number of haptenylated mercaptodextrans required to stabilize the particles depends on the diameter of the particles (see Example 4). Because the number of haptens per molecule of mercaptodextran molecule and number of mercaptodextrans per particle are known the number of haptens per nanoparticle conjugate can be calculated. In the example given here there is a mean of one hapten per mercaptodextran molecule and four mercaptodextran molecules per nanoparticle. Therefore the number of haptens per nanoparticle conjugate is four. By altering the size of the particles the number of mercaptodextrans per nanoparticle, and hence the number of haptens per nanoparticle conjugate, can be varied in such a way that a known number of molecules can be conjugated to each nanoparticle.

### EXAMPLE 4

This Example describes an experiment conducted to assess the relationship between the number of dextrans and nanoparticle diameter. The PDP dextrans (protected mercaptodextrans) were synthesized as described in Example 1 except that only SPDP (no DNPAH-NHS) was used; the aminodextrans into which PDP was substituted had MWs of 10, 40 and 70 kDa (Molecular Probes) and 170, 500 and 2000 kDa (Helix Research). They were titrated against gold nanoparticles (GNPs) of known size and concentration (BBInternational, Cardiff, UK) to find the minimum amounts required to prevent flocculation by PBS. FIG. 18 shows that there is a linear relationship between the minimum numbers of PDP dextran molecules required to prevent flocculation and the square of the particle diameter. It suggests that if the numbers of functional molecules linked to a molecule of dextran prior to conjugation are known, then the numbers of functional molecules per particle can be calculated.

### EXAMPLE 5

This Example describes the use of mercaptodextran nanoparticle conjugates in biomolecular assays. The biomolecular reaction of haptenylated nanoparticle conjugates to antibody-coated paramagnetic microbeads is summarised in FIG. 15. DNP-gold-nanoparticle conjugates (prepared as in Example 3) were slow tilt rotated with paramagnetic beads coated with the corresponding antibody (anti-DNP) in PBS-Tween (PBS+1 mg ml⁻¹ BSA and 0.5% Tween-20). After rotating for ten minutes the beads were magnetically precipitated and the UV/vis spectrum of the supernatant was recorded. FIG. 16 shows how the absorbance spectrum changed as the amount of beads increased; no change was observed in control experiments when rotation was carried out in the presence of 10 μM DNP, or when beads coated with non-specific (anti-mouse) antibodies were used. When magnetically precipitated antibody coated beads were resuspended and rotated with 10 μM DNP, bound nanoparticles (NPs) were released into solution. These results show that gold nanoparticles coated with haptenylated mercaptodextran bind specifically to the corresponding antibody. Results were unaffected by BSA and Tween-20 showing that the haptenylated mercaptodextrans were not displaced from the particles. Picomole amounts of antibody were detected, as shown in FIG. 17.

### EXAMPLE 6

This Example describes an experiment which was conducted in order to modulate conjugate affinity by variation in the number of probe molecules (functional molecules) per nanoparticle. Biotinamidocaproate N-hydroxysuccinimide ester (Sigma) (0.8 mg) in 25 μl of DMSO was added to 2 mg of anti-DNP antibodies (Sigma) in 1 ml of PBS. The solution was slow tilt rotated for 1 hour at room temperature and then purified on Sepahdex G-25. The absorbance of the eluate fraction was 0.894, which corresponds to an antibody concentration of 4.96 μM. Streptavidin coated beads (0.56μ diameter; Bangs Laboratories, Fishers, Ind.) were slow tilt rotated for one hour with biotinylated antibody (50 kg of antibody per mg beads) and then the beads were separated at 9000 g with PBS-Tween as the wash solution. PDP dextrans substituted with dinitrophenyl (DNP) haptens were synthesized by slow dropwise addition of 125 μl of 6(2,4-dinitrophenylamino)-1-aminohexanoic acid [N-hydroxysuccinimide ester] (0.25 mg ml⁻¹ in DMSO) to vigorously stirred solutions of the following amounts of 2000 kDa aminodextran (Helix Research) in 1.6 ml of 0.1 M sodium bicarbonate solution: 100 mg, 50 mg, 25 mg, 10 mg and 5 mg. After one hour of stirring, and standing overnight at 4° C., all solutions were adjusted to a concentration of 5 mg of dextran in 1.6 ml of bicarbonate solution. Then 0.4 ml of ethanol containing 12.5 mM SPDP was added to each of the stirred solutions. After standing overnight the solutions were weighed, dialyzed against water, and weighed again. The final dextran concentrations were calculated from the dilution (weight before dialysis/weight after dialysis) during dialysis. FIG. 19 shows UV/vis spectra of the solutions adjusted to the same concentration. The absorbance peak at 360 nm is due to DNP and the peaks at 235 and 282 nm are due to PDP; there is a small amount of absorbance at short wavelengths due to dextran. From the dextran concentration and the absorbance at 360 nm (1.74×10⁴ M⁻¹ cm⁻¹) it was calculated that there were 1.2, 4.4, 5.9, 8.6 and 12.0 dinitrophenyl (DNP) haptens per molecule of 2000 kDa dextran. Titration shows that a minimum of one 2000 kDa PDP dextran molecule per particle is required to prevent the flocculation of 15 nm GNPs. Therefore the mean numbers of haptens conjugated to 15 nm particles was also 1.2, 4.4, 5.9, 8.6 and 12.0. The same numbers of GNPs conjugated to different numbers of haptens were slow tilt rotated with anti-DNP coated microbeads, for one hour at room temperature, and then the beads were spun down at 300 g in PBS-Tween (twice) and at 9000 g in water (once). The final pellets were evaporated to dryness in a vacuum centrifuge and resuspended in 25 μl of water. They were then transferred to an in-house multiwell plate and imaged with a document scanner as shown in FIG. 20 This shows that the number of GNPs bound by the antibodies increases as the number of haptens per particle increases. Numerical data for the colour of each well was obtained after converting the to the corresponding greyscale image as shown in FIG. 21. These results show that the conjugation method described here can be used to modulate the number of probe molecules conjugated to a nanoparticle, and hence their functional affinity, in a controlled way. This has important implications for the sensitivity of nanoparticle-based bimolecular assays.

### EXAMPLE 7

This Example describes an experiment which was conducted to establish whether reagent limited immunoassays for DNP could be carried out. Anti-DNP antibody was biotinylated and microbeads were coated with biotinylated antibodies as described in Example 6. Immunoassays were carried out by slow tilt rotating DNP conjugate (12 DNP haptens per 15 nm particle) with anti-DNP coated beads and different concentrations of DNP in PBS-Tween for 1 hour at room temperature. At the end of this time the beads were washed, and imaged in a multiwell plate. FIG. 22 shows an image of the plate with the corresponding DNP values. It was possible to distinguish between 5 and 10 ppb of DNP with the unaided eye. FIG. 23 shows the colour density of the wells plotted against DNP concentration.

### EXAMPLE 8

This Example shows how PDP dextrans are conjugated to gold nanoparticles. Synthesis of PDP-Dextrans: 3-(2-pyridyldithio)propionic acid N-hydroxysuccinimide ester (SPDP; Sigma) (10 mg in 0.1 ml of dry DMSO) was reacted with 4 ml of 2 mg ml⁻¹ aminodextran (MW 70 kDa; Molecular Probes, Eugene, Oreg.) in PBS for 2 hours. At the end of this time the solution was dialyzed against water at 4° C. The solution was weighed before and after dialysis to determine the dextran concentration. The corresponding PDP concentration was determined with dithiothreitol (DTT) (Biochem. J. 173 (1978) 723-737). Gold Nanoparticle Titration: Variable amounts of PDP dextran were mixed with 1 ml of 10 nm GNPs (4.5×10¹² particles per ml) and then 0.5 ml of PBSx3 were added. The solutions were then passed through a 0.2μ PES filter (Millipore) and the UV/vis absorbance spectra of the filtrates were recorded. The mean number of primary amines per molecule of 70 kDa aminodextran was 21.5 of which 20.84 were substituted with PDP (pyridydithio propionyl). In Example 3 PDP dextrans were converted to mercaptodextrans prior to conjugation (see also Chem. Commun. (2003) 108-109), but this step can be omitted because the —S—S— bond in PDP is broken on contact with gold. Presumably the pyridine-2-thione released when this bond is broken is also bound to the nanoparticles, but it does not impair assay performance. In the absence of sufficient PDP dextran the gold NPs flocculate when PBS is added. The flocculated particles can be removed with a 0.21μ PES filter. FIGS. 24 and 25 show the effect of varying the dextran concentration on the absorbance spectrum of the filtrate. From a knowledge of the dextran concentration, and the number of NPs per ml, the minimum number of dextran molecules required to prevent flocculation (˜8.5 per 10 nm particle in this example) can be determined, as shown in FIG. 26. Although the dextran prevents flocculation non-specific binding to proteins is still possible, and therefore BSA and Tween-20 are added as blocking agents. The Kₐ value for a single dative covalent bond between sulphur and gold has a value of around 1.53×10⁴ M⁻¹, which is lower than the Kₐ value of a weak antibody-antigen reaction. If all the sulphur atoms (˜21) in a molecule of the PDP dextran form similar bonds, the Kₐ value for a molecule of this dextran with GNPs will be Kₐ²¹ (Kₐ raised to the power of 21=7.6×10⁸⁷ M⁻¹), which is many orders of magnitude higher than any biomolecular Kₐ value.

### EXAMPLE 9

This example describes the conjugation of oligonucleotides to gold nanoparticles and the use of these conjugates in biomolecular assays. Although proteins conjugated to GNPs have been in use for more than three decades, oligonucleotide conjugates only appeared in 1996. The original conjugates were designed to mediate the programmed self-assembly of GNPs in solution (Nature 382 (1996) 607-609), but it was soon realised that they could also be used to detect DNA (J. Am. Chem. Soc. 120 (1998) 1959-1964 and J. Am. Chem. Soc. 122 (2000) 3795-3796). For this purpose two different NPCs are prepared by bonding thiolated oligonucleotides to GNPs. In the presence of target DNA the solution changes colour from red to purple. More recently similar NPCs have also been used to detect PCR products in rapid test devices (Anal. Chem. 75 (2003) 4155-4160), and target molecules hybridised to microarrays (Science, 296 (2002) 1836-1838). All these examples are based on oligonucleotides conjugated to GNPs by a single dative covalent bond. The K value for the equilibrium between monothiolated oligonucleotides and gold has a value of around 4.8×10⁵ M⁻¹ (Ultramicroscopy 91 (2002) 29-36). This implies that the bond between monothiolated oligonucleotides and gold is significantly weaker than the bonds between two complementary 22-mer oligonucleotides (Kₐ˜1×10¹¹ M⁻¹ at 20° C.) (Nucleic Acids Res. 27 (1999) 1719-1727). Clearly a situation in which probe molecules are more likely to dissociate the from NP label than from the target molecule is not satisfactory. It is well known, moreover, that raised temperatures and ionic strengths such as those encountered during PCR accelerate the dissociation process. Recently the conjugation of oligonucleotides (Nucleic Acids Res. 30 (2002) 1558-1562) and antibodies (Bioconjugate. Chem. 11 (2000) 549-556) to GNPs, by two and three sulphur atoms respectively, have been reported. When a molecule is bound to a NP by n identical bonds the Kₐ value for molecules bound by one bond is raised to the power of n. The equilibrium between free and bound molecules may be further shifted in favour of the latter by the local increase in the concentration of bonding atoms and the chelate effect. The example described here takes advantage of these effects by conjugating oligonucleotides to GNPs by up to 17 sulphur atoms.

Microbead Preparation: Oligonucleotide beads were prepared by coating white streptavidin beads (0.56 g diameter; Bangs Laboratories, Fishers, Ind.) with oligonucleotide having a 5′-terminal biotin [5′-ACCGCGTCGCACCTGCCGC-3′] (Qiagen, Cologne, Germany) in PBS-Tween. Precipitation and washing were carried out with wash solution in a centrifuge at 9000 g. Hydrazide substituted PDP-Dextrans: A 25 mg ml⁻¹ solution of C6-Succinimidyl 4-hydrazinonicotinate acetone hydrazone (C6-SANH) (Solulink, San Diego, Calif.) in dry DMSO was used to prepare a 25 mg ml⁻¹ solution of SPDP-NHS. This solution (0.16 ml) was reacted with 4 ml of 2 mg ml⁻¹ aminodextran (MW 70 kDa: Molecular Probes) in PBS, for 2 hours at room temperature. The dextran was purified on Sephadex G-25 with AB (0.1 M sodium acetate, pH 4.5) as the eluant (70 kDa dextran), and the molarities of PDP and hydrazide groups were determined with DTT, and 4-nitrobenzaldehye respectively. The latter determination was carried out as follows: hydrazide substituted PDP dextran (150 μg in 150 μl of MES (: 0.1 M 2-(N-morpholino)ethanesulfonic acid, 0.15 M NaCl, pH 4.7)) was added to 150 MES containing 0.5 mM nitrobenzaldehyde (Solulink, San Diego, Calif.). After standing at room temperature for 2 hours the hydrazine concentration was determined using a value of ε₃₈₀=2×10⁴ cm mol⁻¹ l⁻¹. Oligonucleotide Conjugate: An excess of oligonucleotide with a 5′ terminal aldehyde group [5′-GCGGCAGGTGCGACGCGGT-3′] (Solulink) was reacted with hydrazide substituted PDP dextran (70 kDa) in AB (0.1 M sodium acetate, pH 4.5), overnight at 4° C. At the end of this time unconjugated oligonucleotide were removed with a 30 kDa MWCO centrifugal concentrator (Millipore); the washing solution was ice-cold HPLC grade water. The minimum amount of oligonucleotide PDP dextran (found by titration) that prevented flocculation in the presence of PBS, was conjugated to 10 nm GNPs. Hybridsation to oligonucleotide-coated microbeads was carried out by slow tilt rotation of excess conjugate with 200 μg of beads in hybridisation solution (15 mM sodium citrate, 0.5 M NaCl, 1 mg ml⁻¹ BSA, 1 mg ml⁻¹ glucose, 0.5% Tween-20, pH 7.0), for 1 hour at room temperature. At the end of this time the beads were spun down at 300 g for 15 minutes in wash solution (twice) and at 9000 g in water (once). The final precipitate was evaporated to dryness in a vacuum centrifuge, resuspended in 25 μl of water, and imaged with a document scanner in a multiwell plate. Before conjugation, the oligonucleotides are covalently attached to dextran molecules that are also substituted with a plurality of PDP groups. The molar ratio of PDP to hydrazide in the dextran was 4:1. FIG. 27 shows the UV/vis spectrum of the dextran after MWCO filtration to remove oligonucleotides that were not covalently attached. The peak at 360 nm (of ε₃₆₀=1.8×10⁴ cm mol⁻¹ l⁻¹) corresponds to the hydrazone bonds between the dextran and oligonucleotides. Most of the absorbance at 260 nm (about 87%) is due to the oligonucleotides (ε₂₆₀=1.63×10⁵ cm mol⁻¹ l⁻¹), but the remainder is due to PDP. The structure of the oligonucleotide substituted PDP dextran is shown in FIG. 28. On contact with GNPs the dithiol bonds in PDP are broken, and dative covalent bonds are formed between the dextran and gold. A minimum of 8.5 70 kDa dextran molecules (FIG. 26) are required to prevent flocculation of 10 nm gold NPs, and therefore there was a mean of 34 oligonucleotides per particle. FIG. 29 shows an image the conjugate hybridised to microbeads coated with different amounts of target oligonucleotide; <500 femtomoles of the target can be distinguished with the unaided eye.

### EXAMPLE 10

This example describes the conjugation of biotin to gold nanoparticles and the use of these conjugates in biomolecular assays. The high affinity interaction between biotin and avidin (or streptavidin) is one of the most widely used methods in bioconjugation chemistry. Although the conjugation of avidin to GNPs was first reported in 1984 (J. Histochem. Cytochem. 32 (1984) 124-128), the conjugation of biotin to GNPs was only reported four years ago. Two different methods for conjugating biotin to GNPs have been described. One method is similar to previously reported methods for conjugating monothiolated oligonucleotides to GNPs, (J. Phys. Chem. 105 (2001) 2222-2226) and the other method is based on hydrophobic bonding (Colloid. Surface. A 205 (2002) 15-20). In the latter method GNPs are first coated with a shell of octadecanethiol, and then a second shell of alkyl biotin is hydrophobically conjugated to the first by interdigitation of the alky chains.

Biotinylated PDP-dextran (2000 kDa) was prepared in the same way as hydrazide substituted PDP dextran in Example 9, except 2000 kDa aminodextran (Helix Research, Springfield, Oreg.) was used instead of 70 kDa aminodextran and biotinamidocaproate N-hydroxysuccininide ester (Sigma) was used instead of C6-SANH. Biotin was determined with HABA (Biochem. J. 94 (1965) 23c-24c), and PDP with DTT. The minimum amount of biotinylated PDP dextran (found by titration) that prevented flocculation in the presence of PBS, was conjugated to 15 nm GNPs. Aliquots of the conjugate in PBS-Tween were slow tilt rotated with 200 μg of streptavidin-coated beads for one hour at room temperature. At the end of this time the beads were spun down at 300 g for 15 minutes in wash solution (twice) and at 9000 g in water (once). The final precipitate was evaporated to dryness in a vacuum centrifuge, resuspended in 25 μl of water, and imaged with a document scanner in a multiwell plate. Control experiments were carried out with mercaptodextran nanoparticle conjugate (gold particles conjugated to PDP dextran that was not substituted with biotin). In the present work the mean number of primary amines per molecule of 2000 kDa aminodextran was 351, and the molar ratio of PDP to biotin in the dextran was 24:1. FIG. 30 shows the UV/vis spectrum of biotin substituted PDP dextran after dialysis. The peaks at 234 and 280 nm are due to PDP; biotin does not make a significant contribution to the spectrum and therefore it was determined by displacement of HABA from avidin. The structure of the biotinylated PDP dextran is shown in FIG. 31. A minimum of about one dextran molecule per particle is required to prevent flocculation of 15 mm gold NPs and therefore there was a mean 14.6 biotins per particle. FIG. 32 shows an image of the beads after rotation with a) biotin conjugate and b) mercaptodextran conjugate. The colour density of the spots was determined after converting to a grey scale and plotted on the graph shown in FIG. 33. A graph of colloidal gold in solution is also a curve, even though a graph of absorbance against concentration is linear, indicating that the curvature of the plot is due to the imaging system rather than saturation of the beads by the conjugate.

### EXAMPLE 11

This example describes the conjugation of antibodies to gold nanoparticles and the use of these conjugates in biomolecular assays. The conjugation of antibodies to GNPs is usually carried out by a non-specific procedure that is believed to involve ionic attraction between the negatively charged gold and the positively charged protein, hydrophobic attraction between the protein and the gold surface, and dative covalent bonding between the gold and sulphur atoms within the structure of the protein (Bioconjugate Techniques, Academic Press (1996) pp 593-604). The optimum pH for conjugation is close to the isoelectric point (pKᵢ) of the antibodies, but different antibodies have different pKᵢ values and each one must be determined separately. Polyclonal antibodies have a range of pKᵢ values, and therefore the antibodies that are actually conjugated reflect the conditions rather than the range of antibodies in the original solution. Even monoclonal antibodies may be difficult to conjugate, with mouse subclass IgG3 being particularly challenging. A further drawback of non-specific adsorption is that antibodies are known to dissociate from GNPs (Immuno-gold Labeling In Cell Biology, CRC Press, Boca Raton, Fla., (1989) pp. 49-60 and Histochem. Cytochem. 39 (1991) 37-39) which leads to a decrease in sensitivity. Recently it has been suggested that covalent attachment of antibodies to GNPs may be necessary to harness the full potential of these labels (Anal. Chem. 74 (2002) 1792-1797). In the example described here the problems of non-specific adsorption are avoided by using a covalent method. First the antibodies are covalently linked to PDP dextran by stable hydrazone bonds, and then the dextran is conjugated to the NPs by a process of self-assembly, in which a plurality of sulphur atoms form dative covalent bonds with the gold. Antibody Conjugate: A 5 fold molar excess of succinimidyl 4-formylbenzoate (SFB) (Solulink) in 25 μl of DMSO was reacted with 2 mg of anti-DNP (Sigma) in 1 ml of PBS, for 2 hours at room temperature. The aldehyde-substituted antibody was purified on Sephadex G-25 with ABS (15 mM sodium acetate, 0.15 M NaCl, pH 5.5) as the eluant. The antibody concentration was determined using a value of ε₂₈₀=18×10⁴ cm mol⁻¹ l⁻¹, and the aldehyde concentration with 2-hydrazinopyridine as follows: aldehyde substituted protein (150 μg in 150 μl MES) was added to 150 μl of MES containing 0.5 mM 2-hydrazinopyridine (Solulink). After standing at room temperature for 2 hours the aldehyde concentration was determined using a value of ε₃₆₀=1.8×10⁴ cm mol⁻¹ l⁻¹ An excess of hydrazide substituted PDP dextran (2000 kDa) was reacted with aldehyde-substituted antibody overnight at 4° C., and then antibodies not linked to dextran were removed with a 300 kDa MWCO centrifugal concentrator (Vivascience AG, Hannover, Germany); the washing solution was ice-cold TBS (15 mM Tris, 0.15 M NaCl, 1 mg ml⁻¹ BSA, 1 mg ml⁻¹ glucose, 0.5% Tween-20, pH 7.4). The minimum amount of antibody substituted PDP dextran (found by titration) that prevented flocculation in the presence of PBS, was conjugated to 30 nm GNPs. Reagent limited immunoassays were carried out on lateral flow devices comprising a reagent band of DNP conjugated to a carrier protein, and a reagent band of antibody binding protein, both immobilised on a porous strip. The ends of the strips nearest the DNP bands were immersed in 50 μl aliquots of antibody conjugate containing different concentrations of DNP. Immersion was continued (˜5 minutes) until all of the conjugate had migrated through both reagent bands, and then the strips were dried and imaged with a document scanner. The ratio of PDP to hydrazide in the 2000 kDa dextran was 2.9:1, and there was a mean of 1.4 aldehydes per molecule of antibody. FIG. 34 shows the UV/vis spectrum of antibody substituted PDP dextran after MWCO filtration to remove antibodies that were not linked to the dextran. The antibodies and the PDP both contribute to the peak at 280 nm, but separate determination of PDP showed that 63.9% of the absorbance at this wavelength was due to the antibodies. The molecular ratio of PDP to antibody in the dextran was 17.1:1, which shows that many of the hydrazides did not react with antibodies. This is expected, because an excess of dextran was used, but it is important to add glucose to block any unreacted hydrazides. The structure of the antibody substituted PDP dextran is shown in FIG. 35. The minimum amount of dextran required to prevent flocculation of 30 nm GNPs (1.7×10¹¹ particles per ml) corresponded to a final antibody concentration of 7.3 nM. Therefore there were about 26 antibodies per particle. FIG. 36 shows the results of a series of reagent-limited immunoassays for DNP carried out on lateral flow devices; <50 ppb of DNP can be distinguished with the unaided eye.

### EXAMPLE 12

This example describes an experiment conducted to produce quantum dot (QD) DNP conjugates and the use of these conjugates in biomolecular assays. Small isolated particles (ca 2-10 nm) of compound semiconductors (ZnS, ZnSe, CdS, CdSe, PbS) are often referred to as quantum dots (QDs) (Curr. Opin. Biotech. 13 (2002) 40-46 and Curr. Opin. Solid St. M. Sci. 6 (2002) 365-370). They have the interesting property of converting much of the energy they absorb at wavelengths greater than the lowest energy transition into emission at close to the band edge. Compared with conventional organic fluorophores QDs have a number of advantages: many colours can be excited at the same wavelength; size-tuneable emission spectra; widely separated excitation and emission spectra; resistance to photobleaching; and long decay times compared with organic dyes such as fluorescein. The latter two properties in particular make them attractive alternatives to organic dyes as labels for biomolecular assays and cellular imaging. Before they can be used as labels, however, they must be conjugated to a suitable probe molecule. Most QDs are synthesized with an outer layer of some hydrophobic ligand such as TOPO (trioctylphosphine oxide) (J. Am. Chem. Soc. 115 (1993) 8706-8715 and J. Phys. Chem-US. 100 (1996) 468-471). The challenge is to replace this outer layer with suitable probe molecules without loss of luminescence or colloidal stability. TOPO and similar coatings can be replaced by exchanging them for mercapto and amino ligands such as mercaptoacetic acid (Science 281 (1998) 2016-2018). These exchange reactions are carried out in non-aqueous organic solvents, which preclude the direct conjugation of antibodies and similar molecules. Although they are rapid and reproducible the products are unstable due to dissociation of the ligand. Carrying out exchange reactions under mild aqueous conditions and conjugating molecules to the quantum dots by a plurality of mercapto groups can solve these problems. Although there is no previous report describing the preparation of QD conjugates by ligand exchange under mild aqueous conditions such reactions can easily be demonstrated. 100 μl aliquots of TOPO capped core shell (CdSe/ZnS) QDs in toluene (Evident Technologies, Troy, N.Y.) were precipitated in 1 ml of dry methanol, for 15 minutes at 9000 g. After two further precipitations at 9000 g in methanol, the QDs were resuspended in 50 μl of methanol. The suspensions were added to 1 ml of 1) 50 mM bicarbonate solution and 2) 1 mM mercaptoacetic acid (MA) in 50 mM bicarbonate solution. They were then slow tilt rotated for 24 h in PTFE vials. At the end of this time the QDs that were incubated with MA were soluble in water because thioacetyl molecules terminating in hydrophilic carboxylic acid groups had replaced hydrophobic TOPO. In the absence of MA the QDs adhered to the walls of the PTFE vial. The water soluble QDs cannot be transferred to chloroform showing that the MA is bonded to them and not merely interdigitated with the alkyl chains of the TOPO. This is an important result, because it demonstrates that exchange reactions can be carried out under mild aqueous conditions such as allow the direct conjugation to QDs of molecules that are insoluble in water and/or denatured by organic solvents.

Anti-DNP coated paramagnetic beads were prepared as described in Example except that the beads (2.8 μm; Dynal (UK) Ltd., Bromborough, Wirral, UK) were precipitated and washed magnetically with an MPC-S sample concentrator (Dynal). Haptenylated mercaptodextran was synthesized by adding 50 μl of 20 mM 6(2,4-dinitrophenylamino)-1-aminohexanoic acid in DMF to 5 ml of 170 kDa amino dextran (Helix Research) at a concentration of 2 mg ml⁻¹ in 50 mM bicarbonate solution. After stirring for 2 hours at room temperature 2-iminothiolane (Traut's Reagent; Sigma) was added to a final concentration of 5 mM. After stirring for a further 2 hours the solution was purified on Sephadex G-25. The concentration of DNP groups in the dextran was determined at 360 nm (1.74×10⁴ M⁻¹ cm⁻¹) (Anal. Biochem. 177 (1989) 392-395). The concentration of mercapto groups was determined from the increase in absorbance at 412 nm when freshly reduced and purified mercaptodextran was reacted with Elhman's reagent, with reference to a calibration graph prepared using cysteine solutions (Bioconjugate Techniques, Academic Press (1996) pp. 18-90).

50 μl of TOPO coated QDs (washed as described above) in methanol were added to 0.95 ml of 350 nM freshly purified haptenylated mercaptodextran in 50 mM sodium bicarbonate solution. The solution was slow tilt rotated for 24 hours at room temperature and then the QDs were precipitated for 15 minutes at 9000 g and resuspended in 1 ml of PBS-Tween. After two further precipitations in PBS-Tween at 9000 g, 200 μl aliquots of the QD solution were mixed with 0.7 ml of DNP solution. Then 100 μl of antibody coated paramagnetic beads were added and the mixture was slow tilt rotated for one hour at room temperature. At the end of this time the beads were magnetically precipitated and washed with PBS-Tween three times. The final precipitate was evaporated to dryness in a vacuum centrifuge and resuspended in 10 μl of water 500 nl aliquots were spotted onto a non-fluorescent white plate and imaged with a Spot 2 Camera (Optivision, Ossett, Yorkshire, UK) interfaced with a Leica LM DB2 microscope (Optivision). The beads were excited with UV light and detected by a customized 630 nm filter block (Optivision). The proposed structure of the mercaptodextran is shown in FIG. 37. When the mercaptodextran was slow tilt rotated with the QDs the TOPO was displaced and the haptenylated dextran was conjugated to the NPs by a plurality of mercapto groups. When the DNP QD conjugate was incubated with paramagnetic beads coated with the corresponding antibody, the amount of conjugate bound to the beads decreased as the concentration of DNP in the sample increased, as shown in FIG. 38. These results show that haptenylated mercaptodextran can be conjugated to QDs under mild aqueous conditions, and that the resulting conjugates are suitable for use in bimolecular assays that involve vigorous mixing in the presence of blocking agents such as BSA and detergents such as Tween-20. Persons skilled in the art will recognize that antibody, oligonucleotide and other QD conjugates can be prepared by similar methods.

1. A method for the preparation of nanoparticle conjugates comprising:
a) providing a first reagent comprising a flexible hydrophilic polymer;
b) providing a second reagent comprising at least one functional molecule capable of being substituted into the flexible hydrophilic polymer;
c) providing a third reagent comprising if nanoparticles;
d) contacting the first reagent with the second reagent for a period of time and under conditions effective to allow substitution of the at least one functional molecule into the flexible hydrophilic polymer;
e) before, during and/or after step d) providing the flexible hydrophilic polymer with a plurality of substituents capable, optionally after deprotection, of binding to the nanoparticles to provide an intermediate product comprising the flexible hydrophilic polymer substituted with the at least one functional molecule and a plurality of substituents capable, optionally after deprotection, of binding to the nanoparticles;
f) if necessary, deprotecting the plurality of substituents capable of binding to the nanoparticles; and
g) contacting the, if necessary deprotected, intermediate product of step e) with the third reagent for a period of time and under conditions effective to allow binding of the, if necessary deprotected, intermediate product with the nanoparticles to provide the nanoparticle conjugates wherein the number of functional molecules conjugated per nanoparticle in the final step is controlled by at least one of:
controlling, by means of suitable selection of reagents and reaction conditions, the number of functional molecules substituted into the flexible hydrophilic polymer in step d);
controlling, by means of suitable selection of reagents and reaction conditions, the number of optionally protected substituents capable of binding to the nanoparticles substituted into the flexible hydrophilic polymer in step e); and
controlling, by means of suitable selection of reagents and reaction conditions, the number of intermediate product molecules binding to the nanoparticles in step g).

2. A method according to claim 1 wherein control of the number of functional molecules per nanoparticle is achieved by at least one of:
selecting the relative sizes of the flexible hydrophilic polymer and the nanoparticle to control the number of molecules of flexible hydrophilic polymer, and therefore of optionally deprotected intermediate products, which can be accommodated on the surface of the nanoparticle;
selecting the relative concentrations of the first and second reagents in step d) to control the number of functional molecule (s) substituted into each molecule of flexible hydrophilic polymer; and
selecting the number per molecule of flexible hydrophilic polymer of substituent molecules capable, optionally after deprotection, of binding to the nanoparticles.

3. A method according to claim 1 further comprising determining at least approximately the desired number of, if necessary deprotected, intermediate product molecules to be bound to each nanoparticle in step g) and selecting the relative size of the flexible hydrophilic polymer and the nanoparticle such that the number of, if necessary deprotected, intermediate product molecules which can be accommodated on the surface of each nanoparticle at least approximately matches the desired number.

4. A method according to claim 1 further comprising determining at least approximately the desired number of functional molecule (s) to be substituted into each molecule of flexible hydrophilic polymer in step d) and selecting accordingly the reagent concentrations and reaction conditions in step d).

5. A method according to claim 1 further comprising determining at least approximately the desired number of substituent molecules capable, optionally after deprotection, of binding to the nanoparticles to be substituted into each molecule of flexible hydrophilic polymer in step e) and selecting accordingly the reagent concentrations and reaction conditions in step e).

6. A method according to claim 1 wherein the relative size of the flexible hydrophilic polymer and the nanoparticle are selected to be effective to allow binding in step g) of a controlled number of the, if necessary deprotected, intermediate product molecules with the nanoparticles.

7. A method for the preparation of a nanoparticle conjugates comprising:
i) providing a first reagent comprising a flexible hydrophilic polymer having a plurality of substituents capable, optionally after deprotection, of binding to a nanoparticle;
ii) providing a second reagent comprising one or more functional molecules suitable for binding to target molecules, optionally in a biomolecular assay, and capable of being substituted into the flexible hydrophilic polymer;
iii) providing a third reagent comprising nanoparticles capable of binding to the plurality of substituents of the flexible hydrophilic polymer;
iv) contacting the first reagent with the second reagent for a period of time and under conditions effective to allow the substitution of the at least one functional molecule into the flexible hydrophilic polymer and provide an intermediate product comprising the flexible hydrophilic polymer substituted with the at least one functional molecule; and
v) contacting the intermediate product of step iv) with the third reagent for a period of time and under conditions effective to allow binding of the intermediate product with the nanoparticles to provide the nanoparticle conjugate.

8. A method according to claim 1 wherein the number of functional molecules substituted into the flexible hydrophilic polymer in the intermediate product is determined before the step of contacting the intermediate product with the third reagent.

9. A method according to claim 1 wherein the number of functional molecules per molecule of the flexible hydrophilic polymer in the intermediate product is determined before the step of contacting the intermediate product with the third reagent.

10. A method according to claim 1 further comprising the step of determining the number of intermediate product molecules bound to the nanoparticles in the nanoparticle conjugates.

11. A method according to claim 1 further comprising the step of determining the number of intermediate product molecules bound per nanoparticle in the nanoparticle conjugates.

12. A method according to claim 1 further comprising the step of determining at least approximately the average size of the nanoparticles and selecting the hydrophilic flexible polymer to be of an overall size (considering at least one or more of molecular weight, chain length and degree of chain branching) such that the nanoparticle conjugate is able to accommodate a mean number z of flexible hydrophilic polymer molecules around its surface.

13. A method according to claim 12 wherein z is selected according to the intended application of the nanoparticle conjugate.

14. A method for producing a nanoparticle conjugate comprising:
I) providing a nanoparticle having a surface area x;
II) providing a flexible hydrophilic polymer having a chain length and degree of branching such that a molecule of the polymer has the capacity, when suitably conformed, to envelop a surface area x/y;
III) substituting the polymer with a plurality of conjugation substituents capable of binding to the nanoparticle and with at least one functional molecule capable of imparting a function in a biomolecular assay or other application to the nanoparticle conjugate; and
IV) conjugating approximately y molecules of the polymer to the nanoparticle via the said
plurality of conjugation substituents; wherein the flexible hydrophilic polymer is selected with regard to the variable y to provide a nanoparticle conjugate having an at least approximately predetermined number of flexible hydrophilic polymer molecules per nanoparticle.

15. A nanopartcile conjugate obtained by a method according to claim 1.

16. A nanoparticle conjugate derivable from a method according to claim 1 which comprises on average a single molecule of intermediate product conjugated to each nanoparticle.

17. A nanoparticle conjugate derivable from a method according to claim 1 wherein the nanoparticles are metallic and are produced from Au, Ag, Cu, Pd or composites thereof.

18. A nanoparticle conjugate derivable from a method according to claim 1 wherein the nanoparticles are semiconductors.

19. A nanoparticle conjugate as claimed in claim 18, wherein the nanoparticles are core-shell quantum dots comprising a core having a selected band gap energy and a shell having a greater band gap energy than the core.

20. A semiconductor nanoparticle conjugate as in claim 19 wherein the core of the quantum dot has the formula YX, where Y is selected from Zn, Cd, Hg and combinations thereof, and X is selected from S, Se, Te and combinations thereof, and the shell of the quantum dots has the formula AB, where A is selected from Zn, Cd and mixtures thereof, and B is selected from S, Se, Te and mixtures thereof, such that AB is not identical to YX and wherein AB has a higher band gap energy than the core of the quantum dot.

21. A nanoparticle conjugate derivable from a method according to claim 1, further comprising a nanoparticle conjugated to a flexible hydrophilic polymer having at least one functional molecule thereon, the conjugation being provided by multiple mercapto groups.

22. A nanoparticle conjugate comprising a nanoparticle conjugated to afunctionalised flexible hydrophilic polymer via a plurality of mercapto groups.
